(19) United States
(12) Patent Application Publication
(10) Pub. No.: US 2006/0083053 A1
(43) Pub. Date: Apr. 20, 2006

(54) Magnetic random access memory and method of manufacturing the same

(76) Inventor: Keiji Hosotani, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/094,695

(22) Filed: Mar. 31, 2005

(30) Foreign Application Priority Data
Oct. 15, 2004 (JP) 2004-301653

(51) Int. Cl. G11C 11/00

(52) U.S. Cl. 365/158

(57) ABSTRACT

A magnetic random access memory includes a magnetoresistive element which has a planar shape having a plurality of corners and in which at least one corner has a radius of curvature of 20 nm or less.

### CROSS-REFERENCE TO RELATED APPLICATIONS

This application is based upon and claims the benefit of priority from prior Japanese Patent Application No. 2004-301653, filed Oct. 15, 2004, the entire contents of which are incorporated herein by reference.

### BACKGROUND OF THE INVENTION

1. Field of the Invention

The present invention relates to an MRAM (Magnetic Random Access Memory) having magnetoresistive elements using the TMR (Tunneling Magneto Resistive) effect, and a method of manufacturing the same.

2. Description of the Related Art In recent years, MRAMs (Magnetic Random Access Memories) having MTJ (Magnetic Tunnel Junction) elements using the TMR (Tunneling Magneto Resistive) effect have been proposed. In an MRAM, data is written in each MTJ element made of a magnetic material having unidirectional anisotropy by a current magnetic field generated by two current write wirings which are perpendicular to each other.

A conventional MTJ element is formed by photolithography+etching process using a rectangular reticle. For this reason, an MTJ element has an almost rectangular or elliptical shape with round ends. In this case, the asteroid curve nearly has a rhombic shape, and the write margin is small. Hence, it is difficult to reduce the write current.

On the other hand, in a cross-shaped MTJ element, the asteroid curve in each quadrant forms not a straight line but a curve which steeply curves midway. For this reason, the write margin is large, and the write current can be reduced.

However, after photolithography+etching process in the actual LSI process, the ends of the cross-shaped MTJ element are rounded due to the resolution limit of lithography. Since no sharp cross shape can be obtained, the magnetic characteristic which ensures the simulated asteroid curve cannot be obtained.

In lithography using a resist, it is difficult to control a shape smaller than the wavelength used for exposure. For example, it is hard to suppress the radius of curvature of the edge portion from varying between the MTJ elements. This variation is reflected on the variation in magnetic characteristic between MTJ elements to cause an obstacle to application of MTJ elements to large scale memories.

[Patent Reference 1] Jpn. Pat. Appln. KOKAI Publication No. 2004-071881

### BRIEF SUMMARY OF THE INVENTION

A magnetic random access memory according to a first aspect of the present invention comprises a magnetoresistive element which has a planar shape having a plurality of corners and in which at least one corner has a radius of curvature not more than 20 nm.

A method of manufacturing a magnetic random access memory according to a second aspect of the present invention comprises forming a lower write wiring which runs in a first direction, sequentially forming a first material layer serving as a magnetoresistive element and a second material layer serving as a hard mask above the lower write wiring, patterning the first material layer and the second material layer into a first shape, forming a resist which runs in the first direction across the first shape, patterning the second material layer by using the resist as a mask to form the hard mask having a second shape, removing the resist, forming an insulating film around the first material layer, the insulating film exposing the hard mask and the first material layer, forming an upper write wiring which runs in a second direction different from the first direction across the first shape, and patterning the first material layer by using the upper write wiring and the hard mask as a mask to form the magnetoresistive element having a third shape, the magnetoresistive element having corners whose radius of curvature is not more than 20 nm.

A method of manufacturing a magnetic random access memory according to a third aspect of the present invention comprises forming a lower write wiring which runs in a first direction, forming a material layer serving as a magnetoresistive element above the lower write wiring, patterning the material layer into a first shape, forming a first insulating film around the material layer, the first insulating film exposing the material layer, forming a resist which runs in the first direction across the first shape, patterning the material layer by using the resist as a mask to form the magnetoresistive element having a second shape, the magnetoresistive element having corners whose radius of curvature is not more than 20 nm, removing the resist, and forming an upper write wiring which runs in a second direction different from the first direction across the first shape.

A method of manufacturing a magnetic random access memory according to a fourth aspect of the present invention comprises forming a lower write wiring which runs in a first direction, forming a material layer serving as a magnetoresistive element above the lower write wiring, patterning the material layer into a first shape, forming an insulating film around the material layer, the insulating film exposing the material layer, forming an upper write wiring which runs in a second direction different from the first direction across the first shape, and patterning the material layer by using the upper write wiring as a mask to form the magnetoresistive element having a second shape, the magnetoresistive element having corners whose radius of curvature is not more than 20 nm.

### BRIEF DESCRIPTION OF THE SEVERAL VIEWS OF THE DRAWING

FIGS. 1A to 1F are plan views showing the planar shapes of an MTJ element according to an embodiment of the present invention;

FIGS. 2A to 2C are sectional views showing the sectional shapes of the MTJ element according to the embodiment of the present invention;

FIGS. 3A and 3B are sectional views showing the tunnel junction structures of the MTJ element according to the embodiment of the present invention;

FIGS. 4A to 4H are sectional views showing the interlayer exchange coupling structures of the MTJ element according to the embodiment of the present invention;

FIGS. 5A to 5D are views showing Cell Example 1 of a magnetic random access memory according to the embodiment of the present invention, in which FIG. 5A is a plan view of a memory cell, FIG. 5B is a perspective view of the memory cell, FIG. 5C is a sectional view taken along a line VC-VC in FIG. 5A, and FIG. 5D is a plan view showing the planar shapes of an MTJ element and hard mask;

FIGS. 6A to 9C are views showing steps in manufacturing Cell Example 1 of the magnetic random access memory according to the embodiment of the present invention, in which FIGS. 6A, 7A, 8A, and 9A are plan views of memory cells, FIGS. 6B, 7B, 8B, and 9B are perspective views of the memory cells, FIG. 6C is a sectional view taken along a line VIC-VIC in FIG. 6A, FIG. 7C is a sectional view taken along a line VIIC-VIIC in FIG. 7A, FIG. 8C is a sectional view taken along a line VIIIC-VIIIC in FIG. 8A, and FIG. 9C is a sectional view taken along a line IXC-IXC in FIG. 9A;

FIGS. 10A to 10D are views showing Cell Example 2 of the magnetic random access memory according to the embodiment of the present invention, in which FIG. 10A is a plan view of a memory cell, FIG. 10B is a perspective view of the memory cell, FIG. 10C is a sectional view taken along a line XC-XC in FIG. 10A, and FIG. 10D is a plan view showing the planar shapes of an MTJ element and hard mask;

FIGS. 11A to 14C are views showing steps in manufacturing Cell Example 2 of the magnetic random access memory according to the embodiment of the present invention, in which FIGS. 11A, 12A, 13A, and 14A are plan views of memory cells, FIGS. 11B, 12B, 13B, and 14B are perspective views of the memory cells, FIG. 11C is a sectional view taken along a line XIC-XIC in FIG. 11A, FIG. 12C is a sectional view taken along a line XIIC-XIIC in FIG. 12A, FIG. 13C is a sectional view taken along a line XIIIC-XIIIC in FIG. 13A, and FIG. 14C is a sectional view taken along a line XIVC-XIVC in FIG. 14A;

FIGS. 15A to 15D are sectional views showing details of the steps in manufacturing shown in FIGS. 13A to 13C;

FIGS. 16A and 16B are plan views showing an example of an MTJ element having a convex shape as the memory cell of Cell Example 2 of the magnetic random access memory according to the embodiment of the present invention;

FIGS. 17A to 17D are views showing Cell Example 3 of the magnetic random access memory according to the embodiment of the present invention, in which FIG. 17A is a plan view of a memory cell, FIG. 17B is a perspective view of the memory cell, FIG. 17C is a sectional view taken along a line XVIIC-XVIIC in FIG. 17A, and FIG. 17D is a plan view showing the planar shapes of an MTJ element and hard mask;

FIGS. 18A to 22C are views showing steps in manufacturing Cell Example 3 of the magnetic random access memory according to the embodiment of the present invention, in which FIGS. 18A, 19A, 20A, 21A, and 22A are plan views of memory cells, FIGS. 18B, 19B, 20B, 21B, and 22B are perspective views of the memory cells, FIG. 18C is a sectional view taken along a line XVIIIC-XVIIIC in FIG. 18A, FIG. 19C is a sectional view taken along a line XIXC-XIXC in FIG. 19A, FIG. 20C is a sectional view taken along a line XXC-XXC in FIG. 20A, FIG. 21C is a sectional view taken along a line XXIC-XXIC in FIG. 21A, and FIG. 22C is a sectional view taken along a line XXIIC-XXIIC in FIG. 22A;

FIGS. 23A to 23D are views showing Cell Example 4 of the magnetic random access memory according to the embodiment of the present invention, in which FIG. 23A is a plan view of a memory cell, FIG. 23B is a perspective view of the memory cell, FIG. 23C is a sectional view taken along a line XXIIIC-XXIIIC in FIG. 23A, and FIG. 23D is a plan view showing the planar shapes of an MTJ element and hard mask;

FIGS. 24A to 26C are views showing steps in manufacturing Cell Example 4 of the magnetic random access memory according to the embodiment of the present invention, in which FIGS. 24A, 25A, and 26A are plan views of memory cells, FIGS. 24B, 25B, and 26B are perspective views of the memory cells, FIG. 24C is a sectional view taken along a line XXIVC-XXIVC in FIG. 24A, FIG. 25C is a sectional view taken along a line XXVC-XXVC in FIG. 25A, and FIG. 26C is a sectional view taken along a line XXVIC-XXVIC in FIG. 26A;

FIG. 27 is a perspective view showing Cell Modification 1 of the magnetic random access memory according to the embodiment of the present invention;

FIG. 28 is a perspective view showing Cell Modification 2 of the magnetic random access memory according to the embodiment of the present invention;

FIGS. 29A to 32C are views showing steps in manufacturing Cell Modification 3 of the magnetic random access memory according to the embodiment of the present invention, in which FIGS. 29A, 30A, 31A, and 32A are plan views of memory cells, FIGS. 29B, 30B, 31B, and 32B are perspective views of the memory cells, FIG. 29C is a sectional view taken along a line XXIXC-XXIXC in FIG. 29A, FIG. 30C is a sectional view taken along a line XXXC-XXXC in FIG. 30A, FIG. 31C is a sectional view taken along a line XXXIC-XXXIC in FIG. 31A, and FIG. 32C is a sectional view taken along a line XXXIIC-XXXIIC in FIG. 32A;

FIGS. 33A to 36C are views showing steps in manufacturing Cell Modification 4 of the magnetic random access memory according to the embodiment of the present invention, in which FIGS. 33A, 34A, 35A, and 36A are plan views of memory cells, FIGS. 33B, 34B, 35B, and 36B are perspective views of the memory cells, FIG. 33C is a sectional view taken along a line XXXIIIC-XXXIIIC in FIG. 33A, FIG. 34C is a sectional view taken along a line XXXIVC-XXXIVC in FIG. 34A, FIG. 35C is a sectional view taken along a line XXXVC-XXXVC in FIG. 35A, and FIG. 36C is a sectional view taken along a line XXXVIC-XXXVIC in FIG. 36A;

FIGS. 37A and 37B are views showing a select transistor cell of the magnetic random access memory according to the embodiment of the present invention;

FIGS. 38A and 38B are sectional views showing the parallel state and anti-parallel state of magnetization in the MTJ element according to the embodiment of the present invention;

FIG. 39A is a plan view showing a rectangular MTJ element;

FIG. 39B is a view showing the asteroid curve of the rectangular MTJ element shown in FIG. 39A;

FIG. 40A is a plan view showing a cross-shaped MTJ element;

FIG. 40B is a view showing the asteroid curve of the cross-shaped MTJ element shown in FIG. 40A;

FIGS. 41A and 41B are views showing a select diode cell of the magnetic random access memory according to the embodiment of the present invention;

FIGS. 42A and 42B are views showing a cross-point cell of the magnetic random access memory according to the embodiment of the present invention; and

FIG. 43 is a plan view showing a toggle cell of the magnetic random access memory according to the embodiment of the present invention.

### DETAILED DESCRIPTION OF THE INVENTION

In the embodiment of the present invention, an MTJ (Magnetic Tunnel Junction) element as an example of a magnetoresistive element will be described in [1]. In [2], an MRAM (Magnetic Random Access Memory) having the MTJ element will be described. The same reference numerals denote the same parts throughout the drawings.

[1] MTJ Element

An MTJ element according to the embodiment of the present invention will be described. [1-1] planar shape, [1-2] sectional shape, [1-3] tunnel junction structure, [1-4] interlayer exchange coupling structure, and [1-5] material will be described.

[1-1] Planar Shape

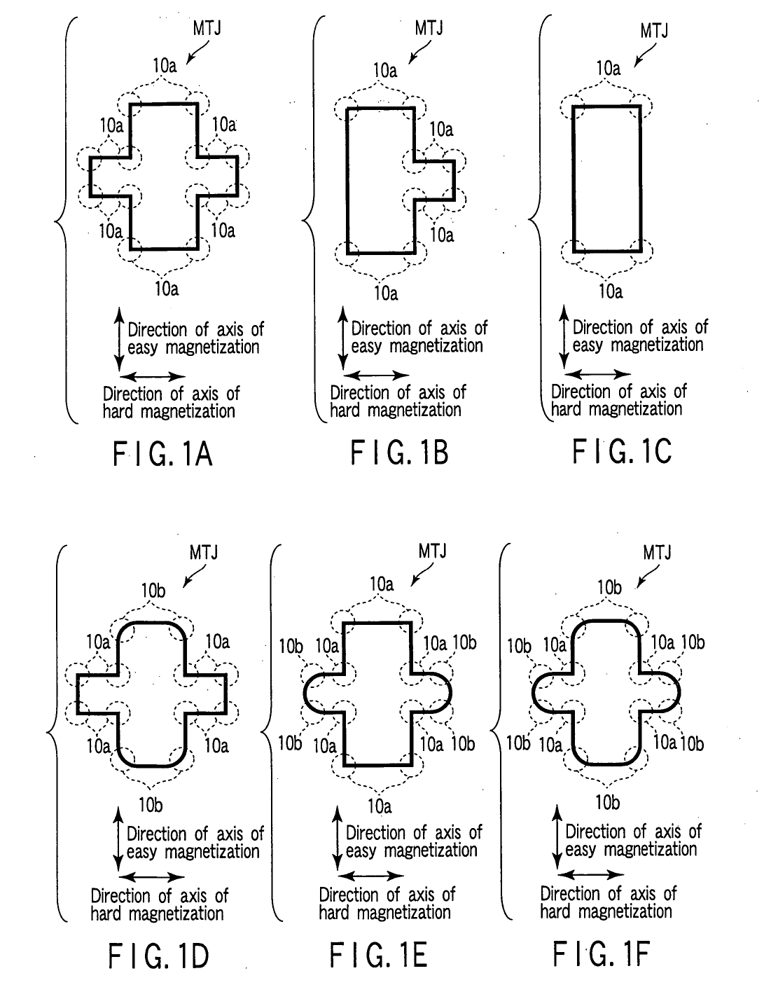

FIGS. 1A to 1F are plan views showing the planar shapes of an MTJ element according to the embodiment of the present invention. The planar shape of the MTJ element will be described below.

As shown in FIGS. 1A to 1F, an MTJ element MTJ according to the embodiment of the present invention has a planar shape with a plurality of corners (portions indicated by dotted circles). The radius of curvature is 20 nm or less at one or more corners. The radius of curvature at one or more corners is preferably 1 nm to 20 nm. A corner having a radius of curvature of 20 nm or less has a sharp shape less than the resolution limit of lithography. Such a corner will be referred to as an angular portion 10a. A round corner whose radius of curvature is more than 20 nm because of the resolution limit of lithography will be referred to as a round portion 10b.

The MTJ element MTJ shown in FIG. 1A has a cross shape formed by crossing two rectangles. In other words, the MTJ element MTJ includes a main body portion which runs in the direction of axis of easy magnetization, and projecting portions which project in the direction of axis of hard magnetization from near the centers of two sides of the main body portion. The angular portions 10a having a radius of curvature of 20 nm or less are formed at all corners of the MTJ element MTJ.

The MTJ element MTJ shown in FIG. 1B has a convex shape having a portion projecting from one side of a rectangle. In other words, the MTJ element MTJ includes a main body portion which runs in the direction of axis of easy magnetization, and a projecting portion which projects in the direction of axis of hard magnetization from near the center of one side of the main body portion. The angular portions 10a having a radius of curvature of 20 nm or less are formed at all corners of the MTJ element MTJ.

The MTJ element MTJ shown in FIG. 1C has a rectangular shape. The angular portions 10a having a radius of curvature of 20 nm or less are formed at all corners of the MTJ element MTJ.

The MTJ element MTJ shown in FIG. 1D has a cross shape formed by crossing two rectangles. In other words, the MTJ element MTJ includes a main body portion which runs in the direction of axis of easy magnetization, and projecting portions which project in the direction of axis of hard magnetization from near the centers of two sides of the main body portion. The round portions 10b having a radius of curvature of 20 nm or more are formed at the ends of the main body portion. The angular portions 10a having a radius of curvature of more than 20 nm are formed at the ends and proximal portions of the projecting portions.

The MTJ element MTJ shown in FIG. 1E has a cross shape formed by crossing two rectangles. In other words, the MTJ element MTJ includes a main body portion which runs in the direction of axis of easy magnetization, and projecting portions which project in the direction of axis of hard magnetization from near the centers of two sides of the main body portion. The angular portions 10a having a radius of curvature of 20 nm or less are formed at the ends of the main body portion and the proximal portions of the projecting portions. The round portions 10b having a radius of curvature of more than 20 nm are formed at the ends of the projecting portions.

The MTJ element MTJ shown in FIG. 1F has a cross shape formed by crossing two rectangles. In other words, the MTJ element MTJ includes a main body portion which runs in the direction of axis of easy magnetization, and projecting portions which project in the direction of axis of hard magnetization from near the centers of two sides of the main body portion. The round portions 10b having a radius of curvature of more than 20 nm are formed at the ends of the main body portion and the ends of the projecting portions. The angular portions 10a having a radius of curvature of 20 nm or less are formed at the proximal portions of the projecting portions.

When the MTJ element is fabricated into a cross shape by using a mask patterned by lithography as before, each corner of the MTJ element has a radius of curvature of more than 20 nm. This is because the corners of the mask are rounded due to the resolution limit of lithography. In a normal lithography process, the i-line of 365 nm or an excimer laser (KrF, 249 nm; ArF, 193 nm) is typically used currently. In the process of fabricating an MTJ element by using a resist shape directly or transferring a resist shape through a hard mask, the radius of curvature of each edge portion of the fabricated shape is the same that of the wavelength, it is difficult to form a pattern having the radius of curvature of ⅕ or more while using variety illumination or special lithography of halftone.

In the embodiment of the present invention, an MTJ element is fabricated without using portions rounded due to the resolution limit of lithography. Hence, sharp corners exceeding the resolution limit of lithography and, for example, corners having right angles can be formed. A method of forming an MTJ element having a sharp shape will be described later.

[1-2] Sectional Shape

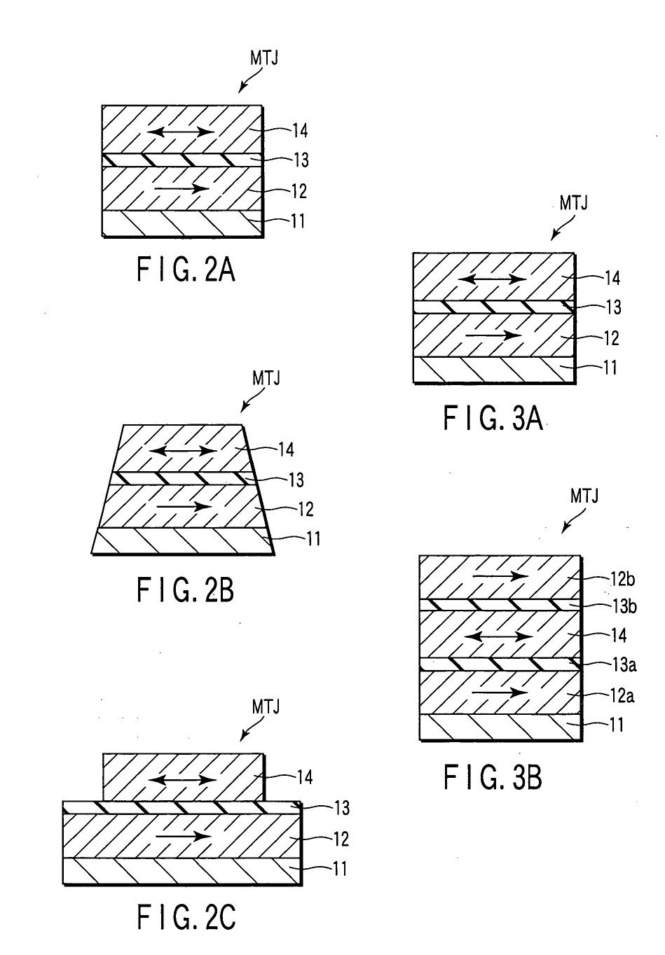

FIGS. 2A to 2C are sectional views of the MTJ element according to the embodiment of the present invention. The sectional shape of the MTJ element will be described below.

As shown in FIGS. 2A to 2C, the MTJ element MTJ according to the embodiment of the present invention has at least a fixed layer (pinned layer) 12 having fixed magnetization, a recording layer (free layer) 14 whose magnetization direction is reversed, and an intermediate layer (e.g., a tunnel insulating layer) 13 sandwiched between the fixed layer 12 and the recording layer 14. In addition, an anti-ferromagnetic layer 11 to fix the magnetization of the fixed layer 12 is formed under the fixed layer 12.

In the MTJ element MTJ, all the side surfaces of the anti-ferromagnetic layer 11, fixed layer 12, intermediate layer 13, and recording layer 14 may continuously be flush with each other (FIGS. 2A and 2B). Alternatively, the side surfaces of the anti-ferromagnetic layer 11, fixed layer 12, intermediate layer 13, and recording layer 14 may form a discontinuous uneven shape (FIG. 2C).

When the MTJ element MTJ shown in FIG. 2A is viewed from the upper side, all the anti-ferromagnetic layer 11, fixed layer 12, intermediate layer 13, and recording layer 14 have the same planar shape.

When the MTJ element MTJ shown in FIG. 2B is viewed from the upper side, the planar shapes of the anti-ferromagnetic layer 11, fixed layer 12, intermediate layer 13, and recording layer 14 become smaller toward the top. That is, the sectional shape is trapezoidal.

The sectional shape shown in FIG. 2C is convex. When the MTJ element MTJ is viewed from the upper side, the planar shape of the anti-ferromagnetic layer 11, fixed layer 12, and intermediate layer 13 is larger than that of the recording layer 14.

Each of the fixed layer 12 and recording layer 14 may have either a single-layered structure made of a ferromagnetic material or a multilayered structure including a plurality of ferromagnetic materials.

[1-3] Tunnel Junction Structure

FIGS. 3A and 3B are sectional views showing the tunnel junction structures of the MTJ element according to the embodiment of the present invention. The tunnel junction structure of the MTJ element will be described below.

As shown in FIGS. 3A and 3B, the MTJ element MTJ according to the embodiment of the present invention may have either a single tunnel junction structure or a double tunnel junction structure.

As shown in FIG. 3A, the MTJ element MTJ having a single tunnel junction structure has one intermediate layer 13 functioning as a tunnel junction layer.

As shown in FIG. 3B, the MTJ element MTJ having a double tunnel junction structure has two intermediate layers 13a and 13b functioning as tunnel junction layers. Hence, the first intermediate layer 13a is formed on one side of the recording layer 14, and a first fixed layer 12a is formed on the first intermediate layer 13a. The second intermediate layer 13b is formed on the other side of the recording layer 14, and a second fixed layer 12b is formed on the second intermediate layer 13b.

[1-4] Interlayer Exchange Coupling Structure

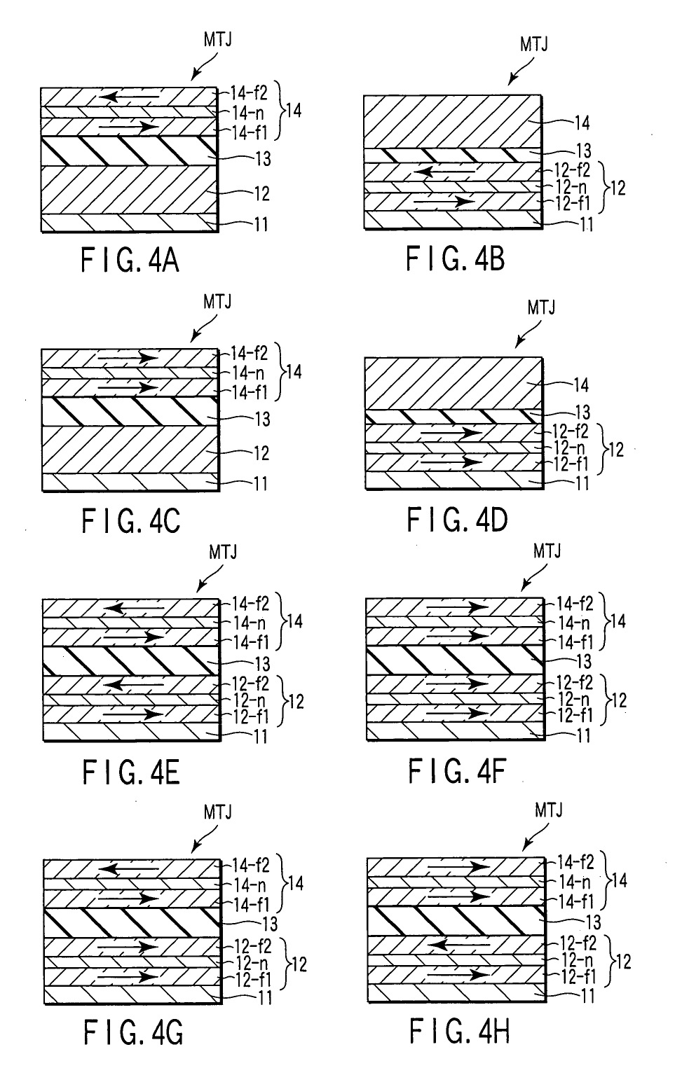

FIGS. 4A to 4H are sectional views showing the interlayer exchange coupling structures of the MTJ element according to the embodiment of the present invention. The interlayer exchange coupling structure of the MTJ element will be described below.

As shown in FIGS. 4A to 4H, in the MTJ element MTJ according to the embodiment of the present invention, at least one of the fixed layer 12 and recording layer 14 may have an anti-ferromagnetic coupling structure or a ferromagnetic coupling structure. In the anti-ferromagnetic coupling structure, interlayer exchange coupling occurs such that the magnetization directions of two ferromagnetic layers which sandwich a nonmagnetic layer are anti-parallel (reverse). In the ferromagnetic coupling structure, interlayer exchange coupling occurs such that the magnetization directions of two ferromagnetic layers which sandwich a nonmagnetic layer are parallel (same).

In the MTJ element MTJ shown in FIG. 4A, the recording layer 14 has the anti-ferromagnetic coupling structure. More specifically, the recording layer 14 has a three-layered structure including a ferromagnetic layer 14-f1, nonmagnetic layer 14-n, and ferromagnetic layer 14-f2. They are magnetically coupled such that the magnetization directions of the ferromagnetic layers 14-f1 and 14-f2 are set in the anti-parallel state.

In the MTJ element MTJ shown in FIG. 4B, the fixed layer 12 has the anti-ferromagnetic coupling structure. More specifically, the fixed layer 12 has a three-layered structure including a ferromagnetic layer 12-f1, nonmagnetic layer 12-n, and ferromagnetic layer 12-f2. They are magnetically coupled such that the magnetization directions of the ferromagnetic layers 12-f1 and 12-f2 are set in the anti-parallel state.

In the MTJ element MTJ shown in FIG. 4C, the recording layer 14 has the ferromagnetic coupling structure. More specifically, the recording layer 14 has a three-layered structure including the ferromagnetic layer 14-f1, nonmagnetic layer 14-n, and ferromagnetic layer 14-f2. They are magnetically coupled such that the magnetization directions of the ferromagnetic layers 14-f1 and 14-f2 are set in the parallel state.

In the MTJ element MTJ shown in FIG. 4D, the fixed layer 12 has the ferromagnetic coupling structure. More specifically, the fixed layer 12 has a three-layered structure including the ferromagnetic layer 12-f1, nonmagnetic layer 12-n, and ferromagnetic layer 12-f2. They are magnetically coupled such that the magnetization directions of the ferromagnetic layers 12-f1 and 12-f2 are set in the parallel state.

In the MTJ element MTJ shown in FIG. 4E, both the recording layer 14 and the fixed layer 12 have the anti-ferromagnetic coupling structure. More specifically, the recording layer 14 has a three-layered structure including the ferromagnetic layer 14-f1, nonmagnetic layer 14-n, and ferromagnetic layer 14-f2. They are magnetically coupled such that the magnetization directions of the ferromagnetic layers 14-f1 and 14-f2 are set in the anti-parallel state. The fixed layer 12 has a three-layered structure including the ferromagnetic layer 12-f1, nonmagnetic layer 12-n, and ferromagnetic layer 12-f2. They are magnetically coupled such that the magnetization directions of the ferromagnetic layers 12-f1 and 12-f2 are set in the anti-parallel state.

In the MTJ element MTJ shown in FIG. 4F, both the recording layer 14 and the fixed layer 12 have the ferromagnetic coupling structure. More specifically, the recording layer 14 has a three-layered structure including the ferromagnetic layer 14-f1, nonmagnetic layer 14-n, and ferromagnetic layer 14-f2. They are magnetically coupled such that the magnetization directions of the ferromagnetic layers 14-f1 and 14-f2 are set in the parallel state. The fixed layer 12 has a three-layered structure including the ferromagnetic layer 12-f1, nonmagnetic layer 12-n, and ferromagnetic layer 12-f2. They are magnetically coupled such that the magnetization directions of the ferromagnetic layers 12-f1 and 12-f2 are set in the parallel state.

In the MTJ element MTJ shown in FIG. 4G, the recording layer 14 has the anti-ferromagnetic coupling structure, and the fixed layer 12 has the ferromagnetic coupling structure. More specifically, the recording layer 14 has a three-layered structure including the ferromagnetic layer 14-f1, nonmagnetic layer 14-n, and ferromagnetic layer 14-f2. They are magnetically coupled such that the magnetization directions of the ferromagnetic layers 14-f1 and 14-f2 are set in the anti-parallel state. The fixed layer 12 has a three-layered structure including the ferromagnetic layer 12-f1, nonmagnetic layer 12-n, and ferromagnetic layer 12-f2. They are magnetically coupled such that the magnetization directions of the ferromagnetic layers 12-f1 and 12-f2 are set in the parallel state.

In the MTJ element MTJ shown in FIG. 4H, the recording layer 14 has the ferromagnetic coupling structure, and the fixed layer 12 has the anti-ferromagnetic coupling structure. More specifically, the recording layer 14 has a three-layered structure including the ferromagnetic layer 14-f1, nonmagnetic layer 14-n, and ferromagnetic layer 14-f2. They are magnetically coupled such that the magnetization directions of the ferromagnetic layers 14-f1 and 14-f2 are set in the parallel state. The fixed layer 12 has a three-layered structure including the ferromagnetic layer 12-f1, nonmagnetic layer 12-n, and ferromagnetic layer 12-f2. They are magnetically coupled such that the magnetization directions of the ferromagnetic layers 12-f1 and 12-f2 are set in the anti-parallel state.

The MTJ element MTJ having the single tunnel junction structure has been described with reference to FIGS. 4A to 4H. This can also be applied to the MTJ element MTJ having the double tunnel junction structure. The fixed layer 12 or recording layer 14 need not always have a three-layered structure including a ferromagnetic layer, nonmagnetic layer, and ferromagnetic layer. The number of layers may be increased.

[1-5] Material

As the material of the fixed layer 12 and recording layer 14, for example, Fe, Co, Ni, or an alloy thereof, magnetite having a high spin polarizability, an oxide such as CrO₂ or RXMnO_{3-Y} (R: rare earth, X: Ca, Ba, or Sr), or a Heusler alloy such as NiMnSb or PtMnSb is preferably used. The magnetic materials may contain a small amount of a nonmagnetic element such as Ag, Cu, Au, Al, Mg, Si, Bi, Ta, B, C, O, N, Pd, Pt, Zr, Ir, W, Mo, or Nb as long as the ferromagnetism is not lost.

As the material of the anti-ferromagnetic layer 11, Fe—Mn, Pt—Mn, Pt—Cr—Mn, Ni—Mn, Ir—Mn, NiO, Fe₂O₃, or the like is preferably used.

As the material of the intermediate layer 13, various dielectric materials such as Al₂O₃, SiO₂, MgO, AlN, Bi₂O₃, MgF₂, CaF₂, SrTiO₂, or AlLaO₃ can be used. These dielectric materials may contain oxygen, nitrogen, or fluorine defects.

[2] Magnetic Random Access Memory

The magnetic random access memory according to the embodiment of the present invention will be described next. [2-1] memory cell and [2-2] write/read method will be described.

[2-1] Memory Cell

A memory cell of the magnetic random access memory according to the embodiment of the present invention has the above-described MTJ element MTJ. Cell examples of the magnetic random access memory according to the embodiment of the present invention will be described below.

### CELL EXAMPLE 1

Cell Example 1 uses an MTJ element MTJ having a cross-shaped planar shape as shown in FIG. 1A.

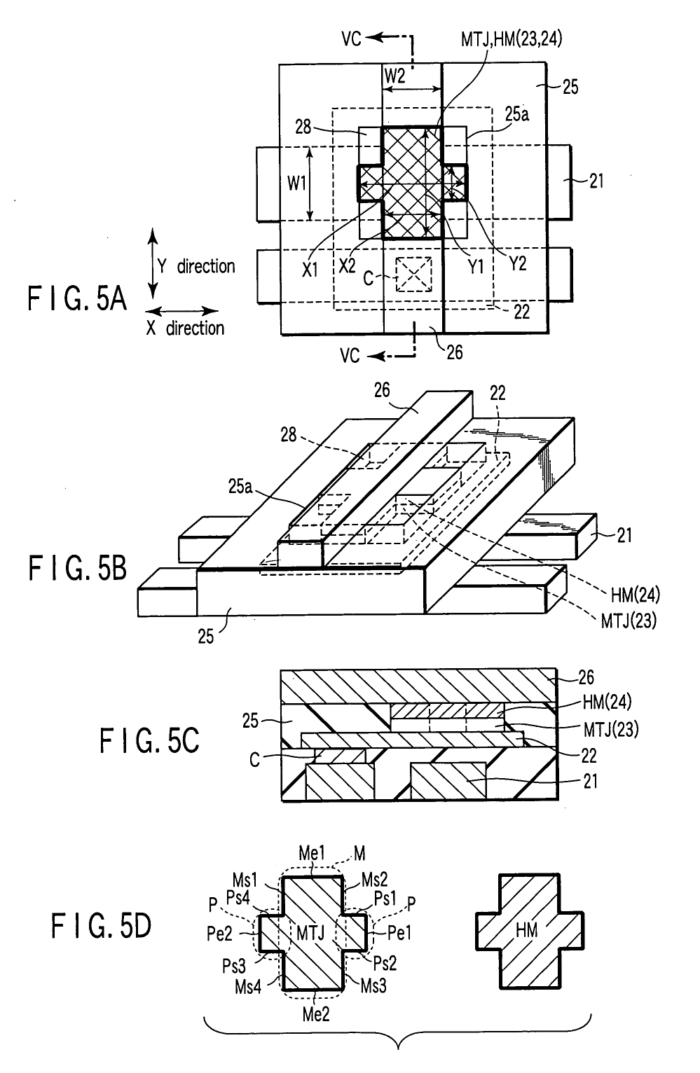

FIGS. 5A to 5D show Cell Example 1 of the magnetic random access memory according to the embodiment of the present invention. The structure of Cell Example 1 will be described below.

As shown in FIGS. 5A to 5D, a memory cell of Cell Example 1 includes the cross-shaped MTJ element MTJ, a hard mask HM formed on the MTJ element MTJ, a base metal layer 22 formed under the MTJ element MTJ, a lower write wiring (e.g., a word line) 21 formed under the MTJ element MTJ, and an upper write wiring (e.g., a bit line) 26 formed above the MTJ element MTJ.

The MTJ element MTJ has a cross shape having a sharp contour as shown in FIG. 1A. That is, all corners of the MTJ element MTJ have a radius of curvature of 20 nm or less.

The cross-shaped MTJ element MTJ includes a main body portion M which runs in the running direction (Y direction or direction of axis of easy magnetization) of the upper write wiring 26, and projecting portions P which project in the running direction (X direction or direction of axis of hard magnetization) of the lower write wiring 21 from the main body portion M. Side surfaces Ms1 to Ms4 of the main body portion M almost coincide with the side surfaces of the upper write wiring 26.

The hard mask HM has almost the same cross shape as the MTJ element MTJ. More specifically, all side surfaces of the hard mask HM almost coincide with all side surfaces of the MTJ element MTJ. The side surfaces of the hard mask HM and those of the MTJ element MTJ are flat.

The concave portions of the cross shapes of the MTJ element MTJ and hard mask HM are filled with an insulating film 28. The insulating film 28 and the convex portions of the cross shapes of the MTJ element MTJ and hard mask HM are buried in an insulating film 25. The upper surface of the hard mask HM and that of the insulating film 25 are almost flush with each other. The upper surface of the hard mask HM and that of the insulating film 25 are almost flat. The insulating films 25 and 28 may be made of different materials or the same material.

The MTJ element MTJ and hard mask HM are formed in a trench 25a in the insulating film 25. End faces Me1, Me2, Pe1, and Pe2 of the convex portions of the cross shapes of the MTJ element MTJ and hard mask HM are in contact with the insulating film 25 (the inner surfaces of the trench 25a). The depth of the trench 25a is almost equal to the sum of thicknesses of the MTJ element MTJ and hard mask HM.

In the cross-shaped MTJ element MTJ, let X1 be the length in the X direction between the projecting portions, X2 be the length of the main body portion M in the X direction, Y1 be the length of the main body portion in the Y direction, and Y2 be the length of the projecting portions in the Y direction. In addition, let W1 be the width of the lower write wiring 21 in the Y direction, and W2 be the width of the upper write wiring 26 in the X direction. In this case, the lengths X1, X2, Y1, and Y2 of the MTJ element MTJ and the widths W1 and W2 of the lower and upper write wirings 21 and 26 have, e.g., relationships given by
(X2=W2)<X1 (1)
Y2<W1<Y1 (2)

The relationships between the lengths X1, X2, Y1, and Y2 of the MTJ element MTJ and the widths W1 and W2 of the lower and upper write wirings 21 and 26 are not limited to inequalities (1) and (2). For example, Y2=W1, W1=W2, W1<W2, or W1>W2 may hold.

When considering the fact that the upper write wiring 26 serves as a mask in fabricating the MTJ element MTJ and hard mask HM, the thickness of the upper write wiring 26 is preferably equal to or larger than the sum of the thicknesses of the MTJ element MTJ and hard mask HM.

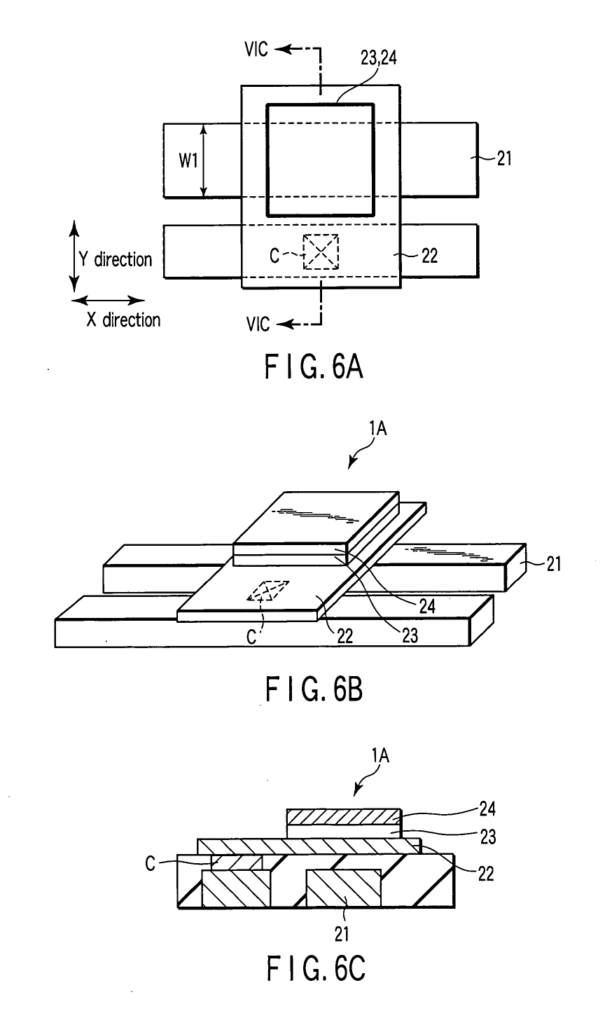

FIGS. 6A to 9C are views showing steps in manufacturing Cell Example 1 of the magnetic random access memory according to the embodiment of the present invention. A method of manufacturing Cell Example 1 will be described below.

First, as shown in FIGS. 6A, 6B, and 6C, the lower write wiring 21 running in the X direction is formed. The base metal layer 22 is formed above the lower write wiring 21. A contact C is formed under the base metal layer 22. An MTJ material layer 23 and hard mask material layer 24 are deposited on the base metal layer 22 and patterned into a desired shape 1A. The desired shape 1A is, e.g., a quadrangle (e.g., a square) whose length in the Y direction is larger than the width W1 of the lower write wiring 21. The hard mask material layer 24 is made of, e.g., Ta.

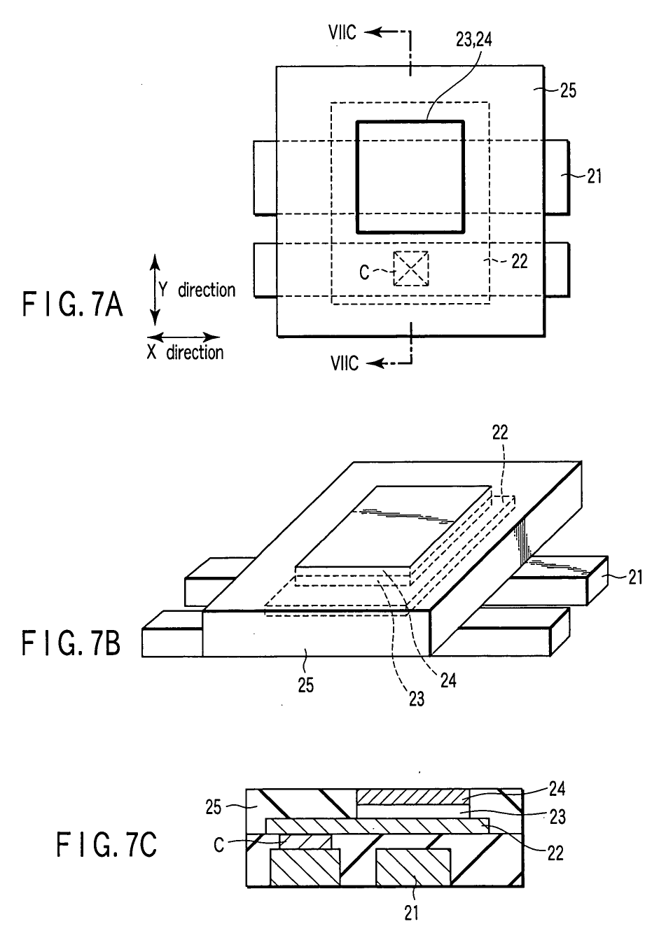

As shown in FIGS. 7A, 7B, and 7C, the insulating film 25 is deposited on the hard mask material layer 24 and base metal layer 22. The insulating film 25 is made of, e.g., a single film of SiO₂, a single film of SiN, or a layered film of SiN/SiO₂. After that, the upper surface of the insulating film 25 is planarized by, e.g., CMP (Chemical Mechanical Polish) or etch back so that the hard mask material layer 24 is exposed.

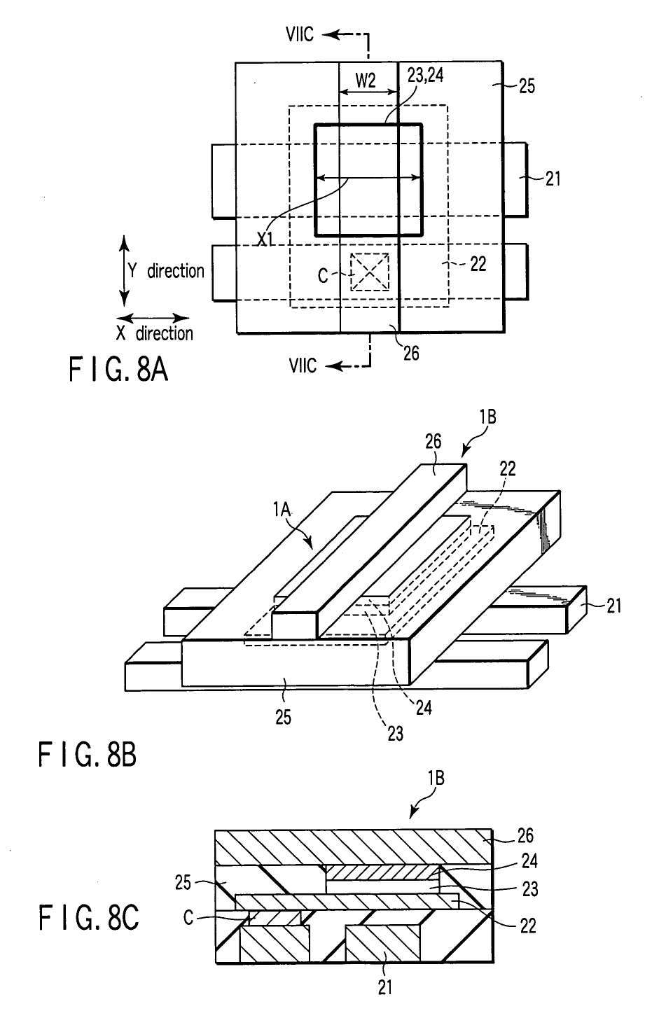

As shown in FIGS. 8A, 8B, and 8C, the upper write wiring 26 is formed on the hard mask material layer 24 and insulating film 25 and patterned into a desired shape 1B by, e.g., lithography and RIE (Reactive Ion Etching). For example, the desired shape 1B runs in the Y direction across the desired shape 1A. The width W2 in the X direction is smaller than the length X1 of the desired shape 1A in the X direction. The upper write wiring 26 is made of, e.g., a single film of Al, a single film of Cu, or a layered film of Al/Cu. The upper write wiring 26 is made of, e.g., a refractory metal (Al/Cu covered with the barrier metal of Ti type, Cu covered with the barrier metal of Ta type, W covered with the barrier metal of Ti type). A magnetic flux concentrating Layer made of a soft magnetic material (permalloy) may be formed around the upper write wiring 26.

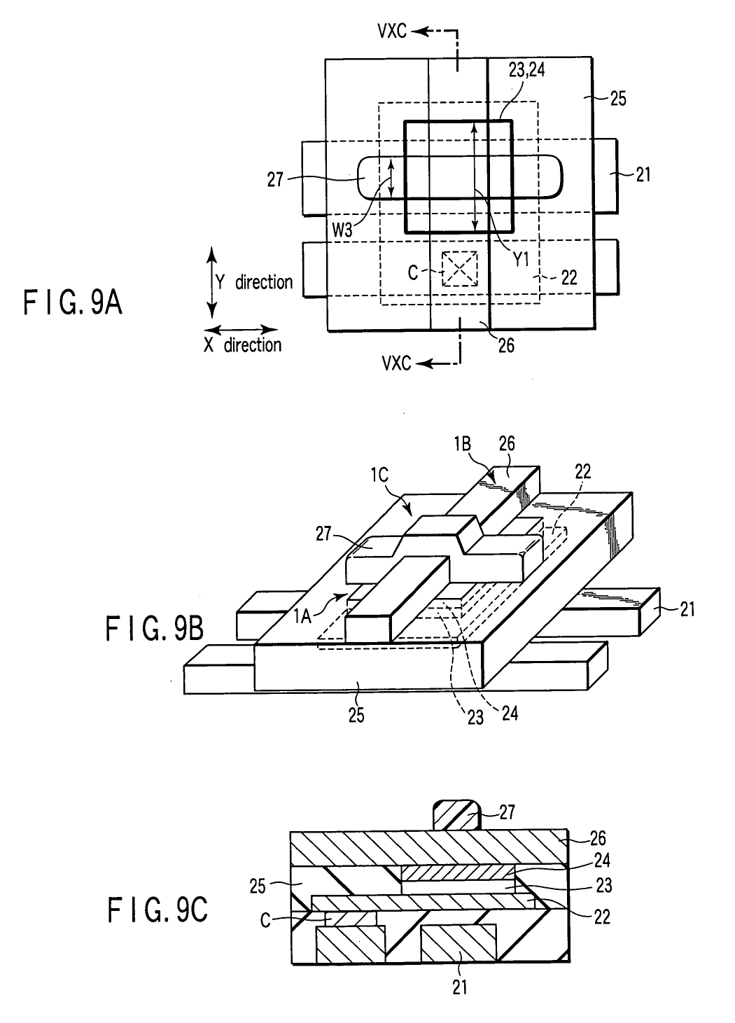

As shown in FIGS. 9A, 9B, and 9C, a resist 27 is applied to the upper surfaces of the upper write wiring 26, hard mask material layer 24, and insulating film 25 and patterned into a desired shape 1C by, e.g., lithography and RIE. For example, the desired shape 1C runs in the X direction across the desired shapes 1A and 1B. A width W3 in the Y direction is smaller than the length Y1 of the desired shape 1A in the Y direction.

The hard mask material layer 24 and MTJ material layer 23 which are exposed from the upper write wiring 26 and resist 27 are etched by using the upper write wiring 26 and resist 27 as a mask. As the etching, for example, anisotropic etching (e.g., RIE), ion milling, or mixed etching of RIE and ion milling is used.

As a result, as shown in FIGS. 5A, 5B, and 5C, the desired shapes 1B and 1C are transferred to the hard mask material layer 24 and MTJ material layer 23 so that the cross-shaped MTJ element MTJ and hard mask HM are formed. Then, the resist 27 is removed. The peripheral portion of the cross-shaped MTJ element MTJ and hard mask HM is filled with the insulating film 28.

According to Cell Example 1, the upper write wiring 26 and resist 27 are patterned into the shapes 1B and 1C which run across the MTJ material layer 23 having the desired shape 1A. In addition to the resist 27, a pattern except the MTJ element MTJ, i.e., the upper write wiring 26 is used as the mask in fabricating the MTJ material layer 23. For these reasons, the hard mask material layer 24 and MTJ material layer 23 which are exposed from the upper write wiring 26 and resist 27 can be etched without using the ends of the upper write wiring 26 and resist 27. Hence, the ends of the upper write wiring 26 and resist 27 which are rounded by lithography are not transferred to the MTJ material layer 23. Only the straight portions of the upper write wiring 26 and resist 27 are transferred to the MTJ material layer 23. For this reason, the MTJ element MTJ can be formed into a desired sharp shape overcoming the resolution limit of lithography, i.e., a cross shape having a sharp contour whose corners have a radius of curvature of 20 nm or less. As a result, the MTJ element MTJ can have a desired magnetic characteristic. The variation in magnetic characteristic between the MTJ elements MTJ can resist and the variation in magnetic characteristic of the element can reduce, thereby the write current can reduce.

### CELL EXAMPLE 2

Cell Example 2 uses an MTJ element MTJ having a cross-shaped planar shape as shown in FIG. 1A, like Cell Example 1. However, Cell Example 2 is different from Cell Example 1 in that the MTJ element MTJ and a hard mask HM have different planar shapes.

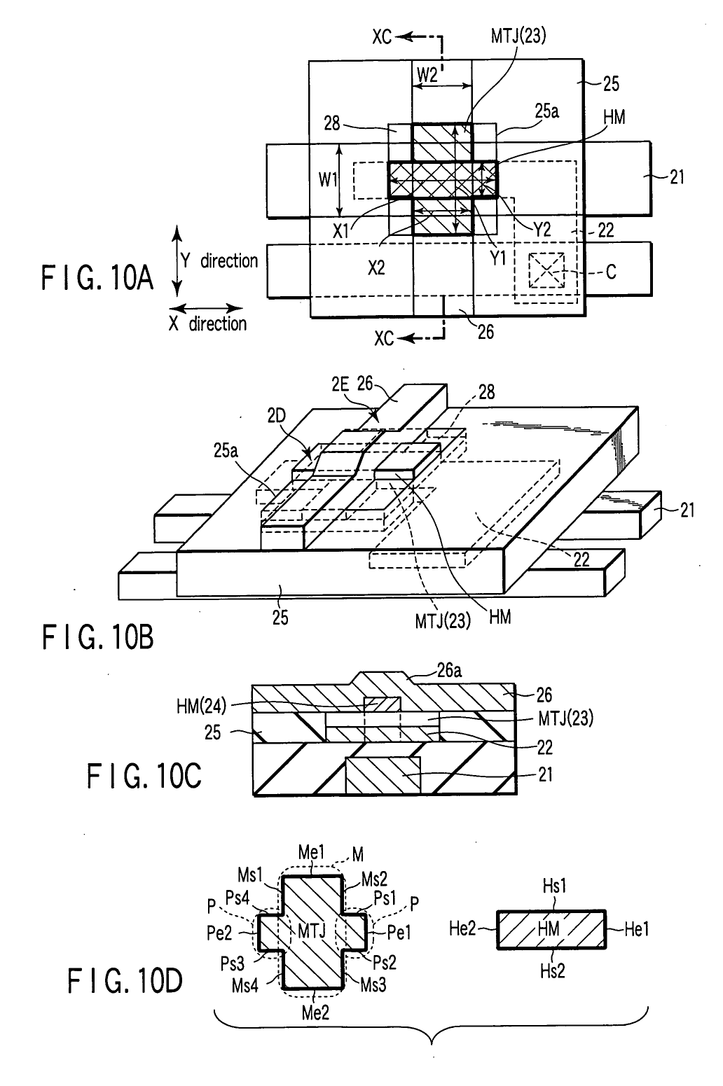

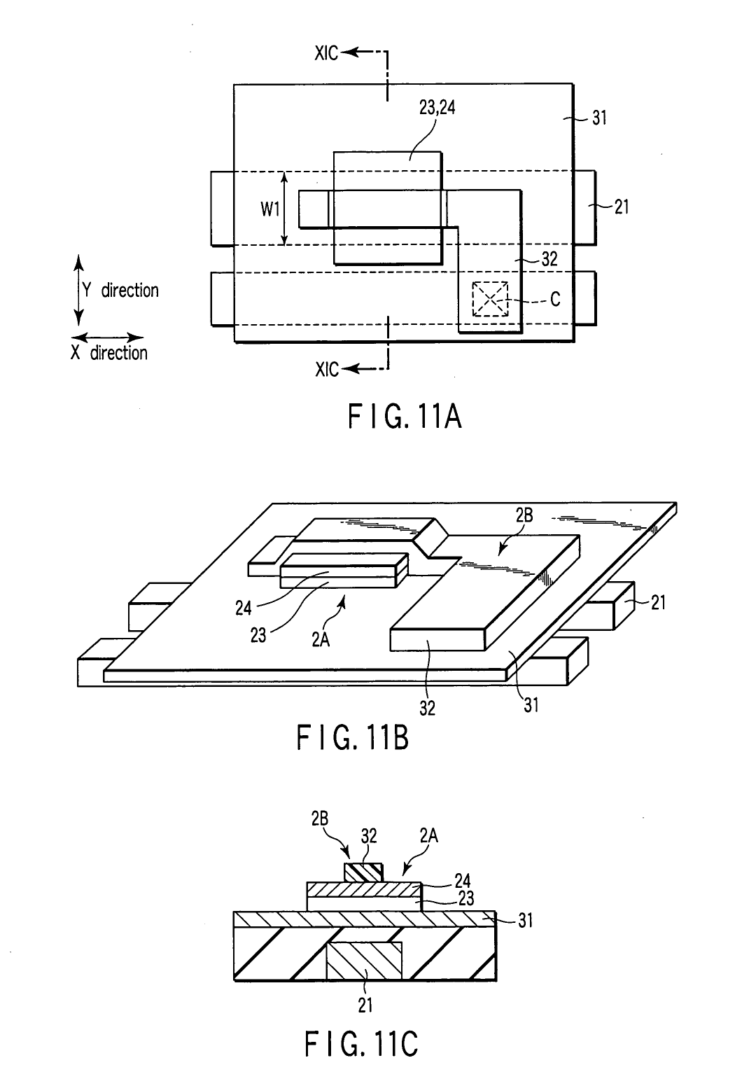

FIGS. 10A to 10D show Cell Example 2 of the magnetic random access memory according to the embodiment of the present invention. The structure of Cell Example 2 will be described below.

As shown in FIGS. 10A to 10D, a memory cell of Cell Example 2 is different from Cell Example 1 mainly in that the MTJ element MTJ and hard mask HM have different planar shapes, and some of the side surfaces of the MTJ element MTJ are in contact with the side surfaces of a base metal layer 22. The structure will be described below in detail.

The MTJ element MTJ has a cross planar shape as shown in FIG. 1A. On the other hand, the hard mask HM has a rectangular shape running in the X direction.

In the cross-shaped MTJ element MTJ, side surfaces Ms1 to Ms4 of a main body portion M almost coincide with the side surfaces of an upper write wiring 26. End faces Me1 and Me2 of the main body portion M almost coincide with the side surfaces of the base metal layer 22. Side surfaces Ps1 to Ps4 of projecting portions P almost coincide with side surfaces Hs1 and Hs2 of the hard mask HM. End faces Pe1 and Pe2 of the projecting portions P almost coincide with end faces He1 and He2 of the hard mask HM.

The planar shape of the base metal layer 22 has a portion which coincides with an opening portion 25a in an insulating film 25.

The upper surface of the MTJ element MTJ is almost flush with the upper surface of the insulating film 25.

The upper write wiring 26 runs in the Y direction across the hard mask HM. The upper write wiring 26 has, above the hard mask HM, a convex portion 26a whose height almost equals the thickness of the hard mask HM.

FIGS. 11A to 14C are views showing steps in manufacturing Cell Example 2 of the magnetic random access memory according to the embodiment of the present invention. A method of manufacturing Cell Example 2 will be described below.

First, as shown in FIGS. 11A, 11B, and 11C, a lower write wiring 21 running in the X direction is formed. A base metal layer 31 is formed above the lower write wiring 21. A contact C is formed under the base metal layer 31. An MTJ material layer 23 and hard mask material layer 24 are sequentially deposited on the base metal layer 31 and patterned into a desired shape 2A. The desired shape 2A is, e.g., a quadrangle (e.g., a square) whose length in the Y direction is larger than a width W1 of the lower write wiring 21. A resist 32 is applied to the upper surfaces of the hard mask material layer 24 and base metal layer 31 and patterned into a desired shape 2B.

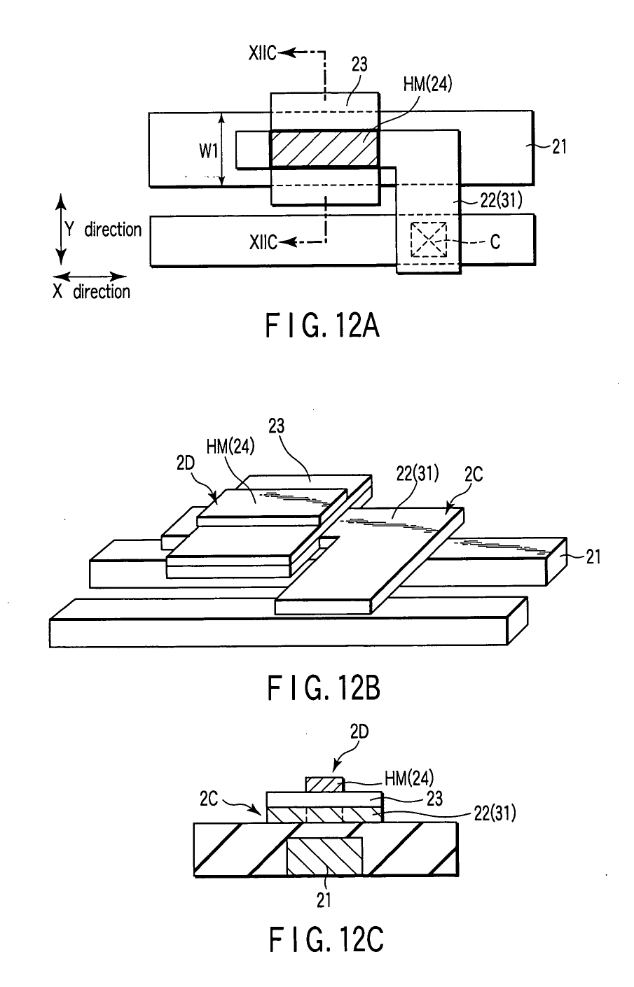

As shown in FIGS. 12A, 12B, and 12C, the hard mask material layer 24 and base metal layer 31 are etched by using the resist 32 as a mask. Accordingly, a base metal layer 22 having a shape 2C as the combination of the desired shapes 2A and 2B is formed, and the hard mask HM having a desired shape 2D is formed. After that, the resist 32 is removed.

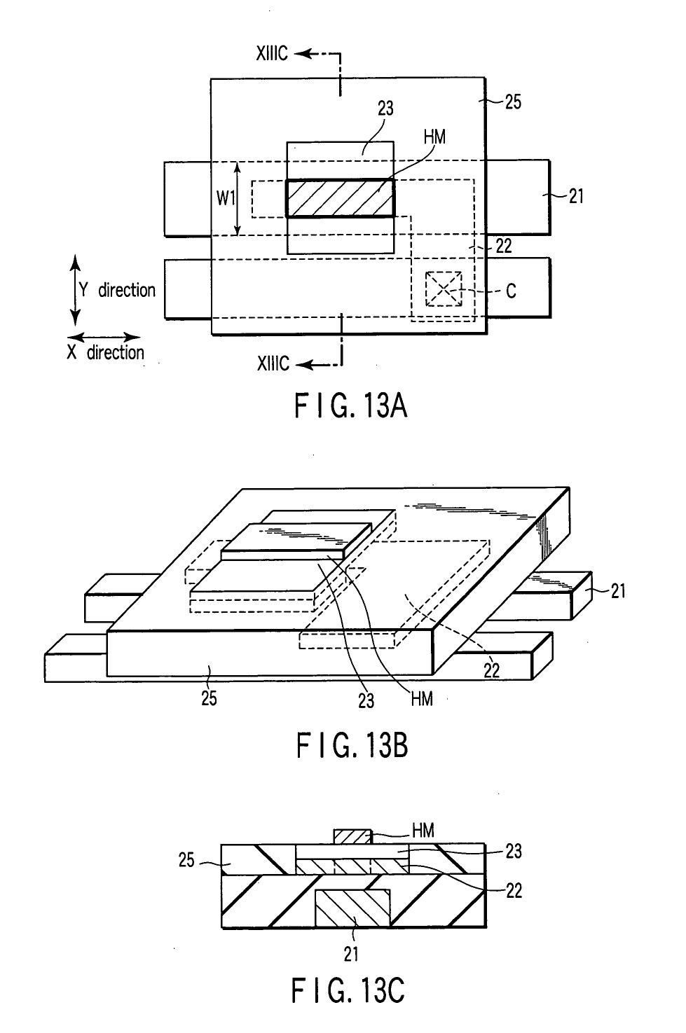

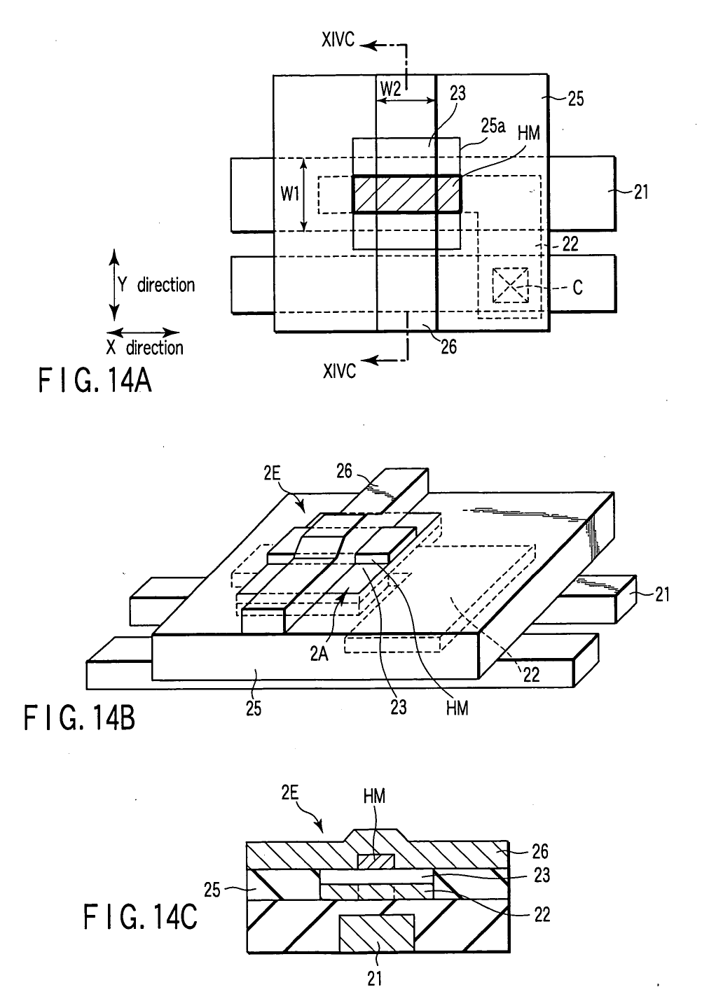

As shown in FIGS. 13A, 13B, and 13C, the insulating film 25 is deposited on the hard mask HM, MTJ material layer 23, and base metal layer 22. The insulating film 25 is made of, e.g., a single film of SiO₂, a single film of SiN, or a layered film of SiN/SiO₂. After that, the upper surface of the insulating film 25 is planarized so that the hard mask HM and MTJ material layer 23 are exposed.

As shown in FIGS. 14A, 14B, and 14C, an upper write wiring 26 is formed on the hard mask HM, MTJ material layer 23, and insulating film 25 and patterned into a desired shape 2E by, e.g., lithography and RIE. For example, the desired shape 2E runs in the Y direction across the hard mask HM and MTJ material layer 23. A width W2 in the X direction is smaller than one side of the desired shape 2A.

As shown in FIGS. 10A, 10B, and 10C, the MTJ material layer 23 which is exposed from the upper write wiring 26 and hard mask HM is etched by using the upper write wiring 26 and hard mask HM as a mask. As a result, the desired shapes 2D and 2E are transferred to the MTJ material layer 23 so that the cross-shaped MTJ element MTJ is formed. Then, the peripheral portion of the MTJ element MTJ and hard mask HM is filled with an insulating film 28.

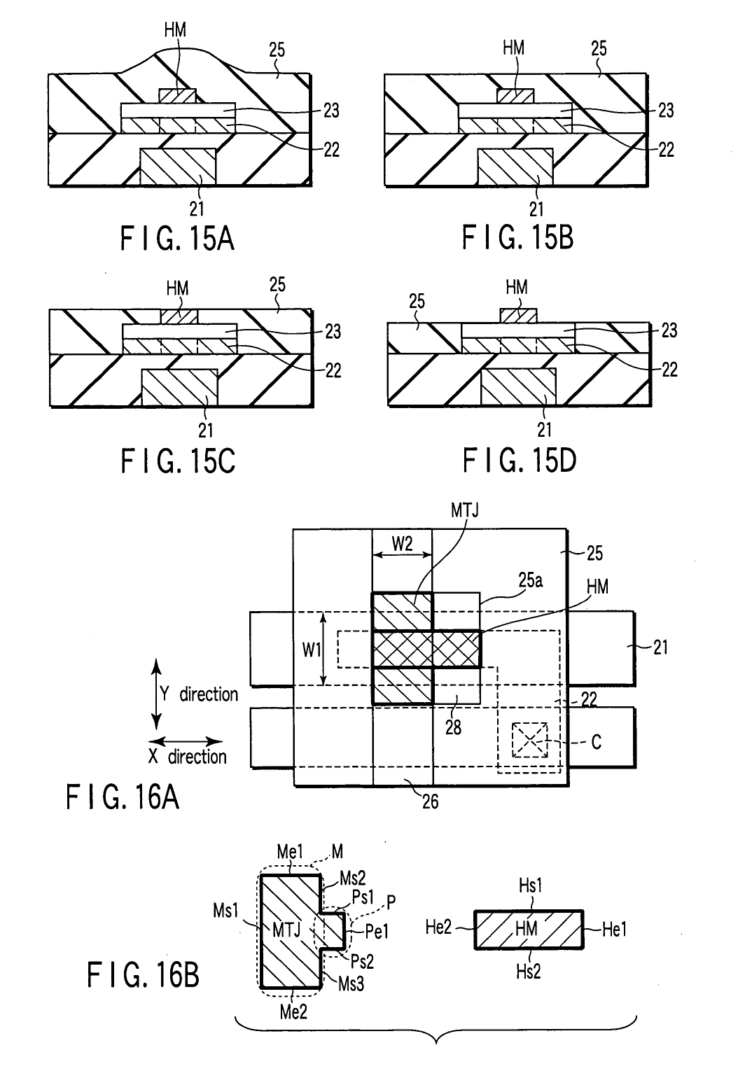

The step shown in FIGS. 13A, 13B, and 13C is executed in accordance with, e.g., the following procedures. First, the insulating film 25 is deposited on the hard mask HM, MTJ material layer 23, and base metal layer 22 (FIG. 15A). The upper surface of the insulating film 25 is planarized by CMP. The insulating film 25 may be planarized until the hard mask HM is exposed (FIG. 15B). Alternatively, the insulating film 25 may be planarized while partially leaving it on the hard mask HM (FIG. 15C). After that, the insulating film 25 is etched by RIE until the MTJ material layer 23 is exposed (FIG. 15D). In this way, the structure shown in FIGS. 13A, 13B, and 13C is formed.

According to Cell Example 2, first, the resist 32 having the shape 2B running across the hard mask material layer 24 having the desired shape 2A is formed. The hard mask material layer 24 is fabricated by using the resist 32 as a mask. Since the hard mask material layer 24 can be etched without using the ends of the resist 32 rounded by lithography, the hard mask HM having a sharp shape can be formed. Next, the upper write wiring 26 having the shape 2E running across the MTJ material layer 23 having the desired shape 2A is formed. The MTJ material layer 23 is fabricated by using the upper write wiring 26 and hard mask HM as a mask. Accordingly, the MTJ material layer 23 can be etched without using the ends of the upper write wiring 26 rounded by lithography.

Hence, the ends of the upper write wiring 26 and resist 32 which are rounded by lithography are not transferred to the MTJ element MTJ. Only the straight portions of the upper write wiring 26 and hard mask HM are transferred to the MTJ element MTJ. For this reason, the MTJ element MTJ can be formed into a desired sharp shape overcoming the resolution limit of lithography, i.e., a cross shape having a sharp contour whose corners have a radius of curvature of 20 nm or less. As a result, the MTJ element MTJ can have a desired magnetic characteristic. The variation in magnetic characteristic between the MTJ elements MTJ can resist and the variation in magnetic characteristic of the element can reduce, thereby the write current can reduce.

The MTJ element MTJ having a convex shape as shown in FIG. 1B can also be formed by using the method of manufacturing Cell Example 2. For example, when the upper write wiring 26 is laid out such that its side surfaces coincide with those of the MTJ material layer 23, as shown in FIGS. 16A and 16B, the MTJ element MTJ can have the convex shape. In this case, in the MTJ element MTJ, the side surfaces Ms1 to Ms3 of the main body portion M almost coincide with the side surfaces of the upper write wiring 26. The end faces Me1 and Me2 of the main body portion M almost coincide with the side surfaces of the base metal layer 22. The side surfaces Ps1 and Ps2 and end face Pe1 of the projecting portion P almost coincide with the side surfaces Hs1 and Hs2 and end face He1 of the hard mask HM.

### CELL EXAMPLE 3

Cell Example 3 uses an MTJ element MTJ having a rectangular planar shape as shown in FIG. 1C.

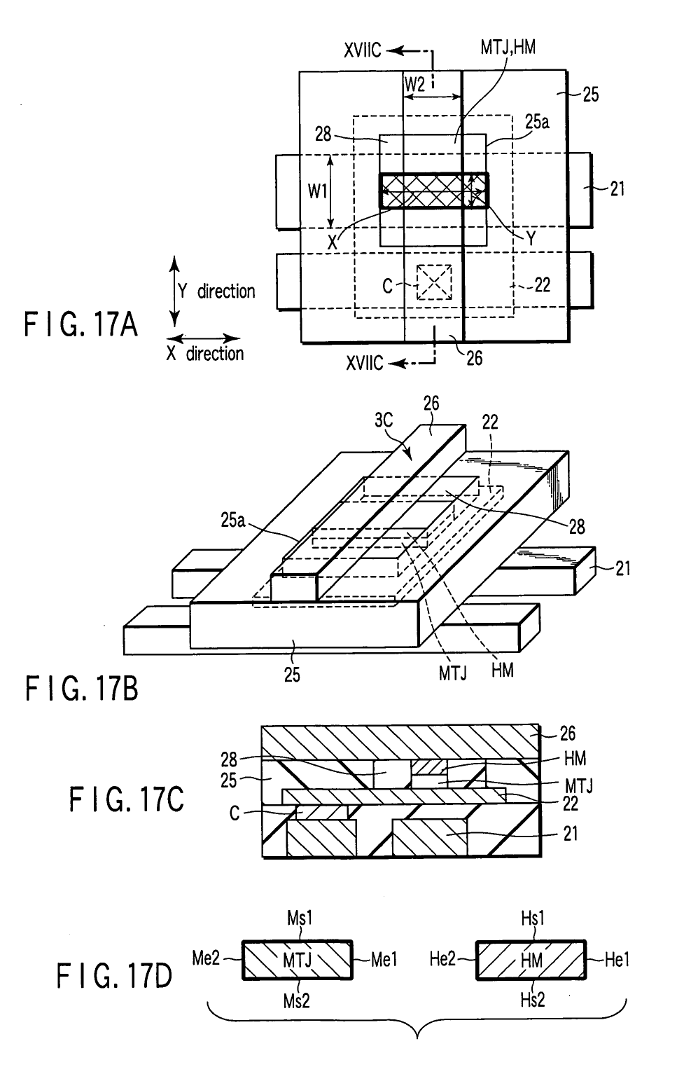

FIGS. 17A to 17D show Cell Example 3 of the magnetic random access memory according to the embodiment of the present invention. The structure of Cell Example 3 will be described below.

As shown in FIGS. 17A to 17D, a memory cell of Cell Example 3 is different from Cell Example 1 mainly in that the MTJ element MTJ has a rectangular planar shape. The structure will be described below in detail.

In Cell Example 3, the MTJ element MTJ has a sharp rectangular planar shape as shown in FIG. 1C. More specifically, all corners of the MTJ element MTJ have a radius of curvature of 20 nm or less.

The planar shape of a hard mask HM is almost the same as the MTJ element MTJ. More specifically, side surfaces Hs1 and Hs2 and end faces He1 and He2 of the hard mask HM almost coincide with side surfaces Ms1 and Ms2 and end faces Me1 and Me2 of the MTJ element MTJ.

The MTJ element MTJ and hard mask HM have rectangular shapes running in the X direction. In the MTJ element MTJ, the X direction is the direction of axis of easy magnetization, and the Y direction is the direction of axis of hard magnetization.

The end faces Me1 and Me2 of the MTJ element MTJ and the end faces He1 and He2 of the hard mask HM are in contact with an insulating film 25.

The upper surface of the hard mask HM and those of the insulating films 25 and 28 are almost flush with each other. The upper surface of the hard mask HM and those of the insulating films 25 and 28 are almost flat. The insulating films 25 and 28 may be made of different materials or the same material.

Let X be the length of the MTJ element MTJ in the X direction, and Y be the length of the MTJ element MTJ in the Y direction. In addition, let W1 be the width of a lower write wiring 21 in the Y direction, and W2 be the width of an upper write wiring 26 in the X direction. In this case, the lengths X and Y of the MTJ element MTJ and the widths W1 and W2 of the lower and upper write wirings 21 and 26 have, e.g., relationships given by
W2<X (3)
Y<W1 (4)

The relationships between the lengths X and Y of the MTJ element MTJ and the widths W1 and W2 of the lower and upper write wirings 21 and 26 are not limited to inequalities (3) and (4). For example, Y=W1 may hold.

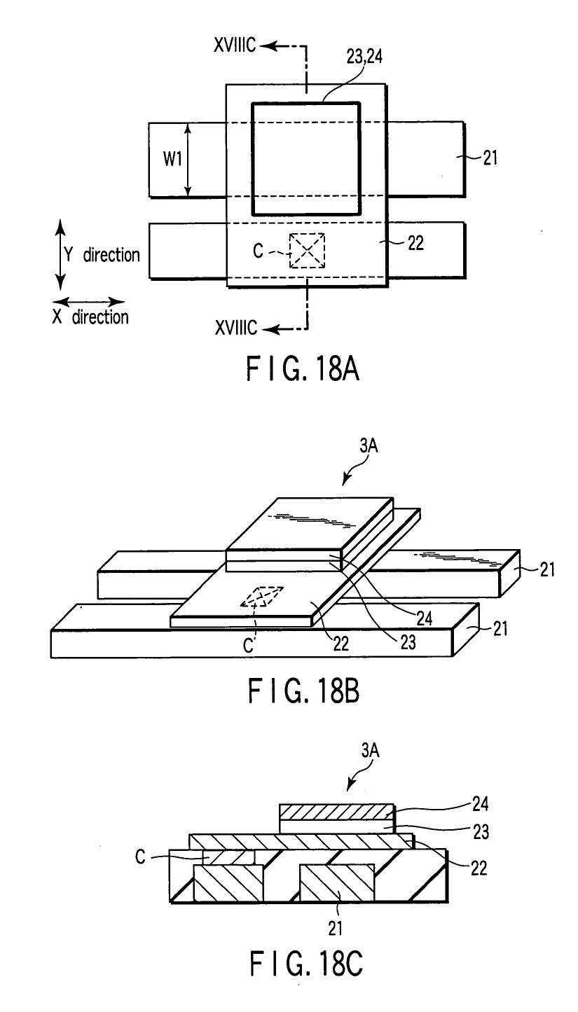

FIGS. 18A to 22C are views showing steps in manufacturing Cell Example 3 of the magnetic random access memory according to the embodiment of the present invention. A method of manufacturing Cell Example 3 will be described below.

First, as shown in FIGS. 18A, 18B, and 18C, the lower write wiring 21 running in the X direction is formed. A base metal layer 22 is formed above the lower write wiring 21. A contact C is formed under the base metal layer 22. An MTJ material layer 23 and hard mask material layer 24 are deposited on the base metal layer 22 and patterned into a desired shape 3A. The desired shape 3A is, e.g., a quadrangle (e.g., a square) whose length in the Y direction is larger than the width W1 of the lower write wiring 21. The hard mask material layer 24 is made of, e.g., Ta.

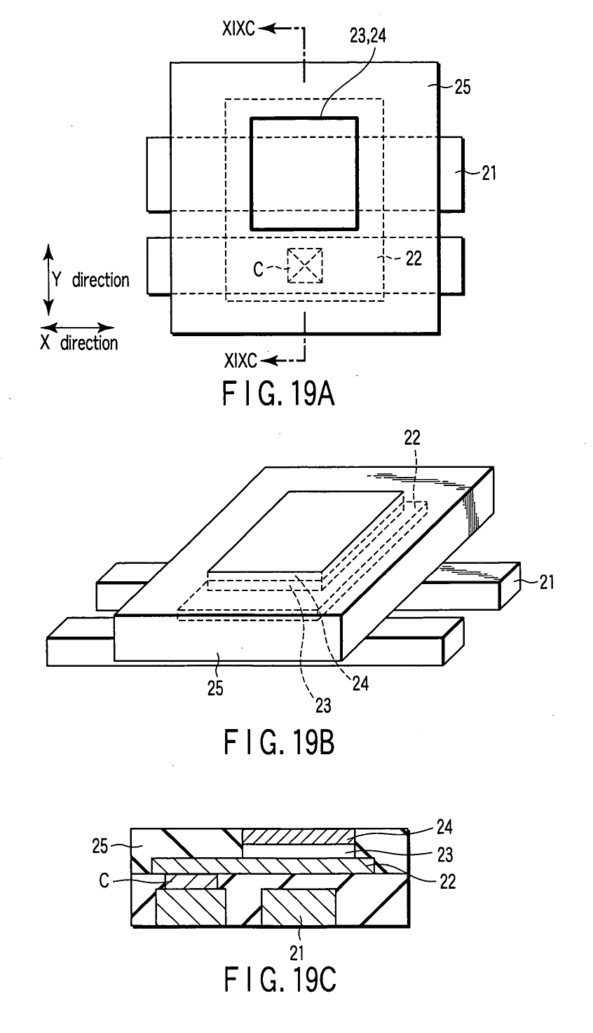

As shown in FIGS. 19A, 19B, and 19C, the insulating film 25 is deposited on the hard mask material layer 24 and base metal layer 22. The insulating film 25 is made of, e.g., a single film of SiO₂, a single film of SiN, or a layered film of SiN/SiO₂. After that, the upper surface of the insulating film 25 is planarized by, e.g., CMP or etch back so that the hard mask material layer 24 is exposed.

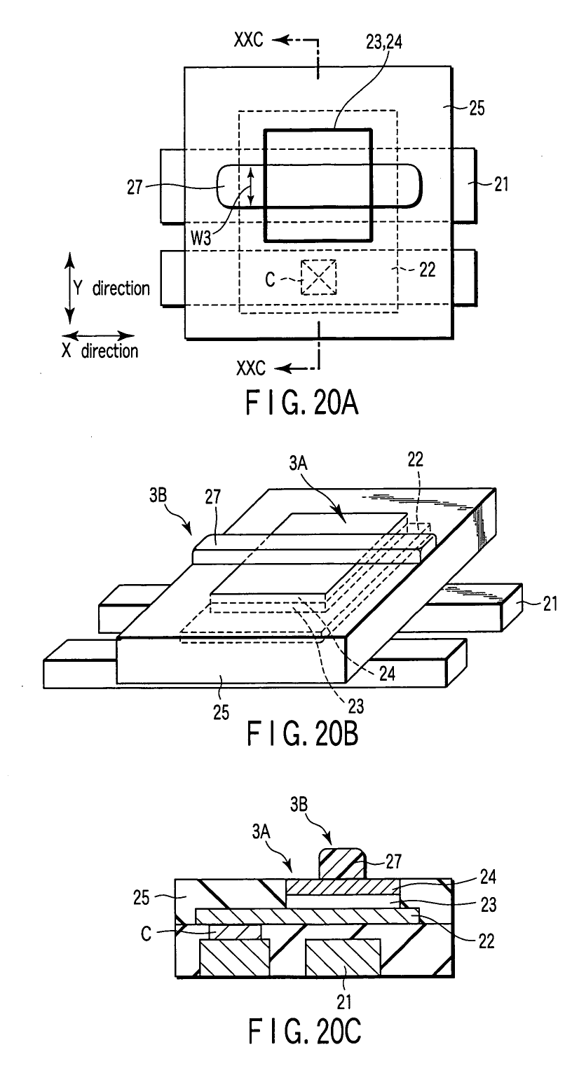

As shown in FIGS. 20A, 20B, and 20C, a resist 27 is applied to the upper surfaces of the hard mask material layer 24, and insulating film 25 and patterned into a desired shape 3B by, e.g., lithography and RIE. For example, the desired shape 3B runs in the X direction across the desired shape 3A. A width W3 in the Y direction is smaller than the length Y of the desired shape 3A in the Y direction.

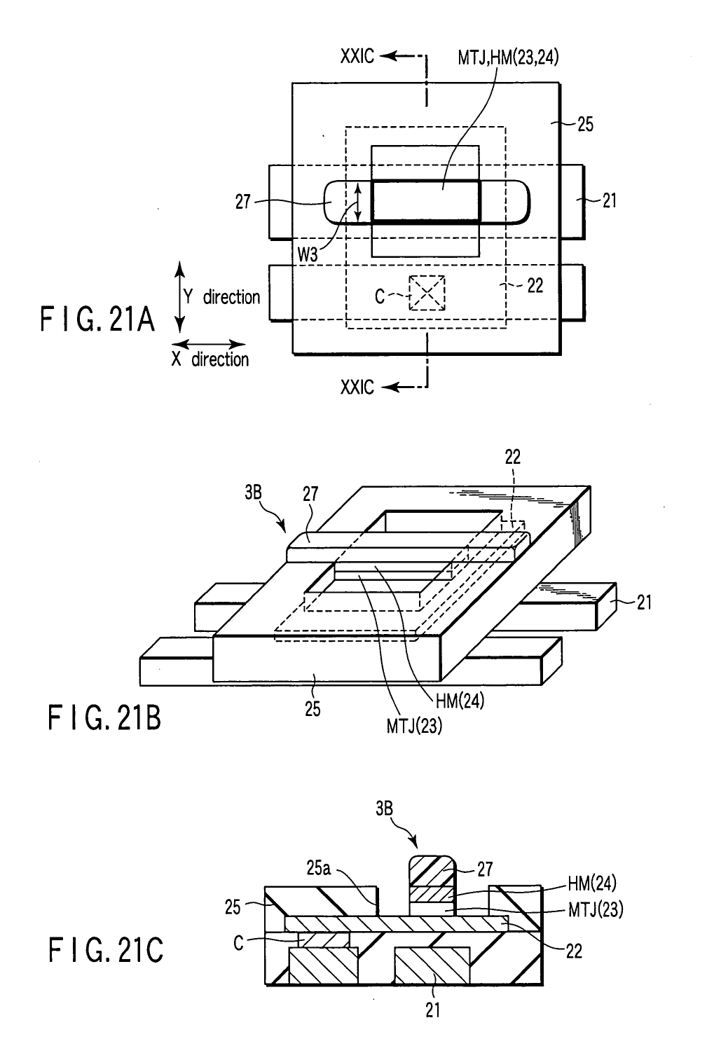

As shown in FIGS. 21A, 21B, and 21C, the hard mask material layer 24 and MTJ material layer 23 which are exposed from the resist 27 are etched by using the resist 27 as a mask. As the etching, for example, anisotropic etching (e.g., RIE), ion milling, or mixed etching of RIE and ion milling is used. As a result, the desired shape 3B is transferred to the hard mask material layer 24 and MTJ material layer 23 so that the rectangular MTJ element MTJ and hard mask HM are formed. Then, the resist 27 is removed.

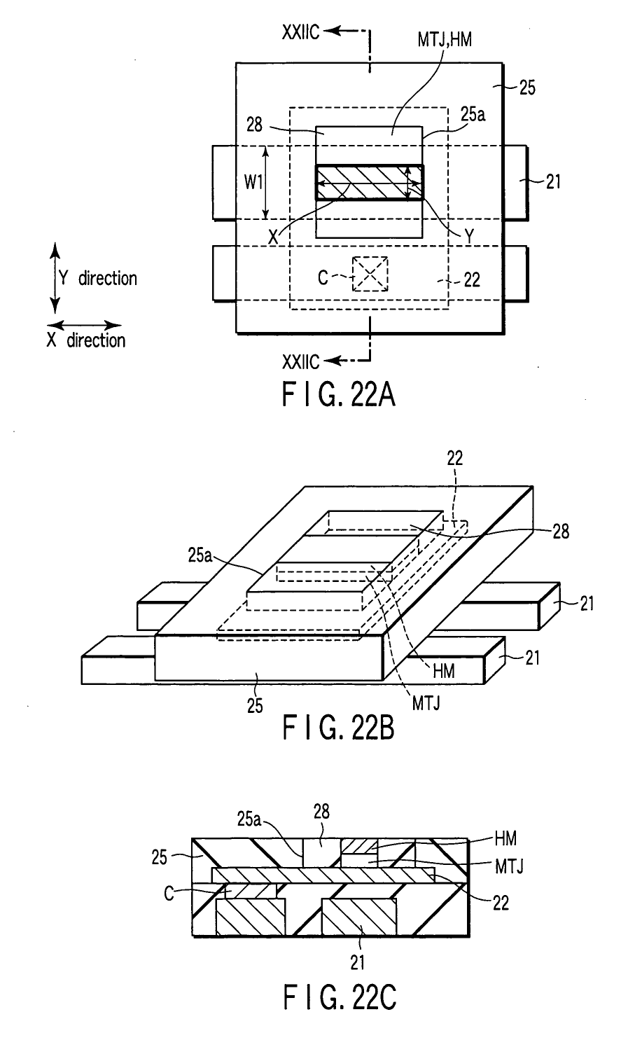

As shown in FIGS. 22A, 22B, and 22C, the insulating film 28 is deposited on the hard mask HM, insulating film 25, and base metal layer 22. The upper surface of the insulating film 28 is planarized by, e.g., CMP or etch back until the hard mask HM and insulating film 25 are exposed. Accordingly, the peripheral portion of the MTJ element MTJ and hard mask HM is filled with the insulating film 28.

As shown in FIGS. 17A, 17B, and 17C, the upper write wiring 26 is formed and patterned into a desired shape 3C by, e.g., lithography and RIE. For example, the desired shape 3C runs in the Y direction across the MTJ element MTJ and hard mask HM. The width W2 in the X direction is smaller than one side of the desired shape 3A. The upper write wiring 26 is made of, e.g., a single film of Al, a single film of Cu, or a layered film of Al/Cu.

According to Cell Example 3, the resist 27 is patterned into the shape 3B which runs across the MTJ material layer 23 having the desired shape 3A. The resist 27 is used as the mask in fabricating the MTJ material layer 23. For these reasons, the hard mask material layer 24 and MTJ material layer 23 which are exposed from the resist 27 can be etched without using the ends of the resist 27. Hence, the ends of the resist 27 which are rounded by lithography are not transferred to the MTJ element MTJ. Only the straight portions of the resist 27 are transferred to the MTJ element MTJ. For this reason, the MTJ element MTJ can be formed into a desired sharp shape overcoming the resolution limit of lithography, i.e., a rectangular shape having a sharp contour whose corners have a radius of curvature of 20 nm or less. As a result, the MTJ element MTJ can have a desired magnetic characteristic. The variation in magnetic characteristic between the MTJ elements MTJ can resist and the variation in magnetic characteristic of the element can reduce, thereby the write current can reduce.

### CELL EXAMPLE 4

Cell Example 4 uses an MTJ element MTJ having a rectangular planar shape as shown in FIG. 1C, like Cell Example 3. In Cell Example 4, some of the side surfaces of the MTJ element MTJ coincide with the side surfaces of the upper write wiring.

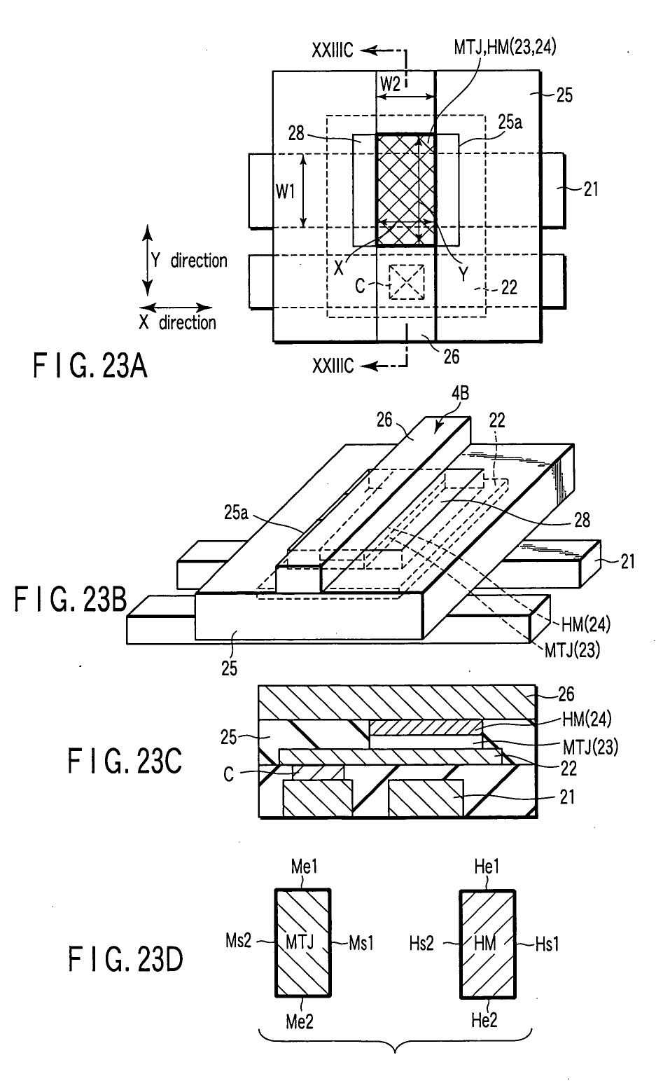

FIGS. 23A to 23D show Cell Example 4 of the magnetic random access memory according to the embodiment of the present invention. The structure of Cell Example 4 will be described below.

As shown in FIGS. 23A to 23D, a memory cell of Cell Example 4 is different from Cell Example 3 mainly in that some of the side surfaces of the MTJ element MTJ coincide with the side surfaces of an upper write wiring 26. The structure will be described below in detail.

In Cell Example 4, the MTJ element MTJ and a hard mask HM have almost the same rectangular shape running in the Y direction. In the MTJ element MTJ, the Y direction is the direction of axis of easy magnetization, and the X direction is the direction of axis of hard magnetization.

Side surfaces Ms1 to Ms4 of the MTJ element MTJ and side surfaces Hs1 and Hs2 of the hard mask HM almost coincide with the side surfaces of the upper write wiring 26. These side surfaces are flat.

End faces Me1 and Me2 of the MTJ element MTJ the end faces He1 and He2 of the hard mask HM are in contact with an insulating film 25.

Let X be the length of the MTJ element MTJ in the X direction, and Y be the length of the MTJ element MTJ in the Y direction. In addition, let W1 be the width of a lower write wiring 21 in the Y direction, and W2 be the width of the upper write wiring 26 in the X direction. In this case, the lengths X and Y of the MTJ element MTJ and the widths W1 and W2 of the lower and upper write wirings 21 and 26 have, e.g., relationships given by
W2=X (5)
W1<Y (6)

The relationships between the lengths X and Y of the MTJ element MTJ and the widths W1 and W2 of the lower and upper write wirings 21 and 26 are not limited to equation (5) and inequality (6). For example, Y=W1 may hold.

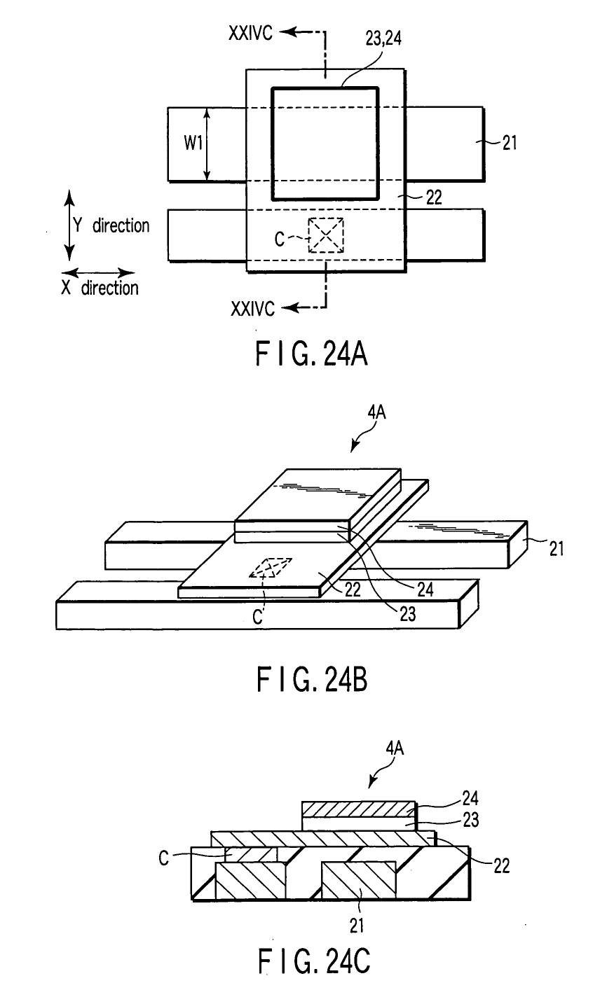

FIGS. 24A to 26C are views showing steps in manufacturing Cell Example 4 of the magnetic random access memory according to the embodiment of the present invention. A method of manufacturing Cell Example 4 will be described below.

First, as shown in FIGS. 24A, 24B, and 24C, the lower write wiring 21 running in the X direction is formed. A base metal layer 22 is formed above the lower write wiring 21. A contact C is formed under the base metal layer 22. An MTJ material layer 23 and hard-mask material layer 24 are deposited on the base metal layer 22 and patterned into a desired shape 4A. The desired shape 3A is, e.g., a quadrangle (e.g., a square) whose length in the Y direction is larger than the width W1 of the lower write wiring 21. The hard mask material layer 24 is made of, e.g., Ta.

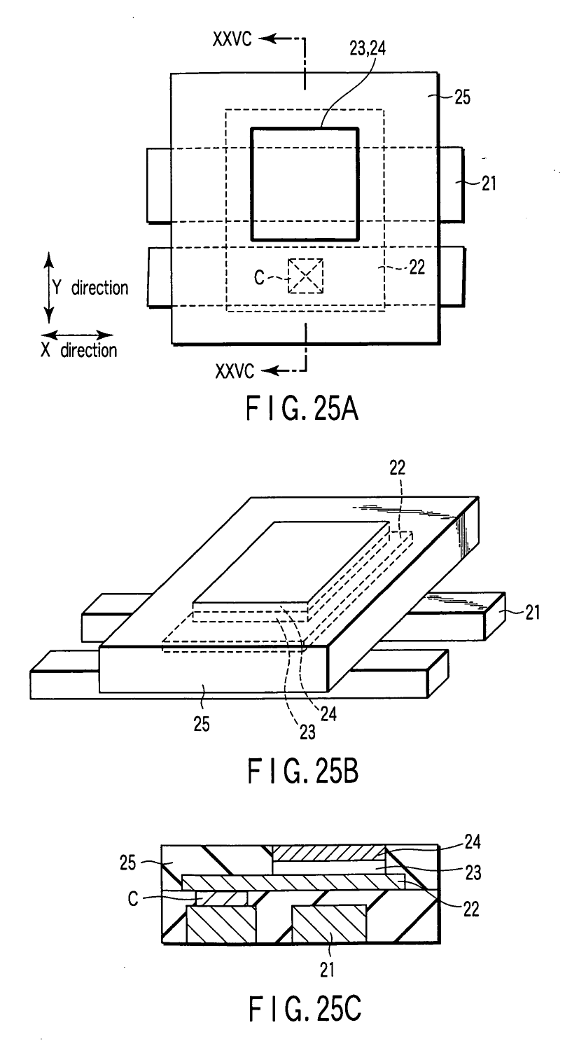

As shown in FIGS. 25A, 25B, and 25C, the insulating film 25 is deposited on the hard mask material layer 24 and base metal layer 22. The insulating film 25 is made of, e.g., a single film of SiO₂, a single film of SiN, or a layered film of SiN/SiO₂. After that, the upper surface of the insulating film 25 is planarized by, e.g., CMP or etch back so that the hard mask material layer 24 is exposed.

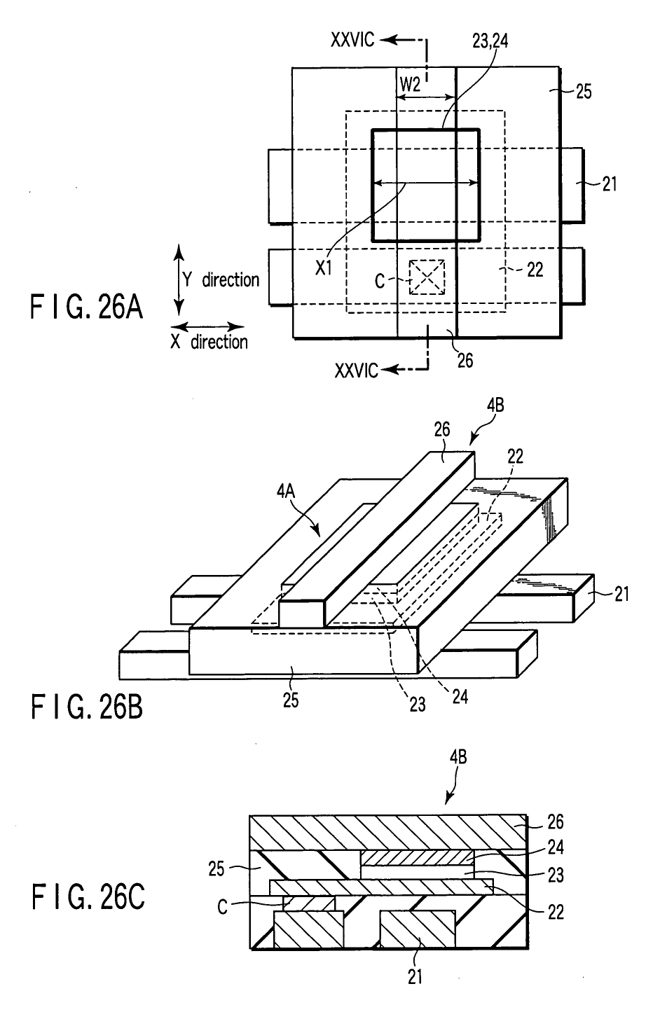

As shown in FIGS. 26A, 26B, and 26C, the upper write wiring 26 is formed on the hard mask material layer 24 and insulating film 25 and patterned into a desired shape 4B by, e.g., lithography and RIE. For example, the desired shape 4B runs in the Y direction across the desired shape 4A. The width W2 in the X direction is smaller than a length X1 of the desired shape 4A. The upper write wiring 26 is made of, e.g., a single film of Al, a single film of Cu, or a layered film of Al/Cu.

As shown in FIGS. 23A, 23B, and 23C, the hard mask material layer 24 and MTJ material layer 23 which are exposed from the upper write wiring 26 are etched by using the upper write wiring 26 as a mask. As the etching, for example, anisotropic etching (e.g., RIE), ion milling, or mixed etching of RIE and ion milling is used. As a result, the desired shape 4B is transferred to the hard mask material layer 24 and MTJ material layer 23 so that the rectangular MTJ element MTJ and hard mask HM are formed. Then, the peripheral portion of the rectangular MTJ element MTJ and hard mask HM is filled with an insulating film 28.

According to Cell Example 4, the upper write wiring 26 is patterned into the shape 4B which runs across the MTJ material layer 23 having the desired shape 4A. The upper write wiring 26 is used as the mask in fabricating the MTJ material layer 23. For these reasons, the hard mask material layer 24 and MTJ material layer 23 which are exposed from the upper write wiring 26 can be etched without using the ends of the upper write wiring 26. Hence, the ends of the upper write wiring 26 which are rounded by lithography are not transferred to the MTJ element MTJ. Only the straight portions of the upper write wiring 26 are transferred to the MTJ element MTJ. For this reason, the MTJ element MTJ can be formed into a desired sharp shape overcoming the resolution limit of lithography, i.e., a rectangular shape having a sharp contour whose corners have a radius of curvature of 20 nm or less. As a result, the MTJ element MTJ can have a desired magnetic characteristic. The variation in magnetic characteristic between the MTJ elements MTJ can resist and the variation in magnetic characteristic of the element can reduce, thereby the write current can reduce.

(Cell Modification 1)

In Cell Modification 1, the pattern of the hard mask HM is formed in relief in Cell Examples 1 to 4. The structure of Cell Example 1 will be exemplified here. However, this modification can also be applied to Cell Examples 2 to 4, as a matter of course.

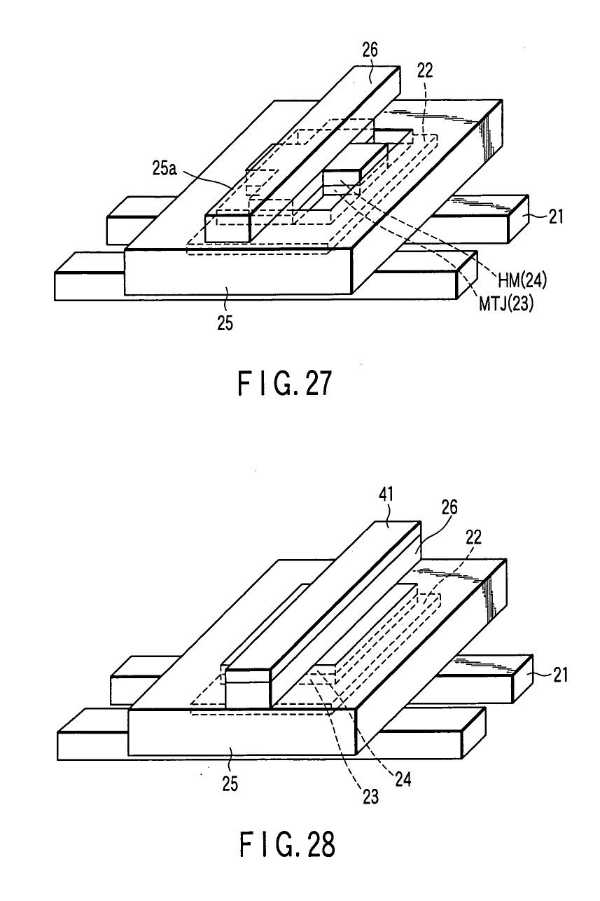

FIG. 27 shows Cell Modification 1 of the magnetic random access memory according to the embodiment of the present invention. As shown in FIG. 27, in Cell Modification 1, the upper surface of the hard mask HM is higher than the upper surface of the insulating film 25 which buries the peripheral portion of the MTJ element MTJ and hard mask HM. This structure can be formed by etching part of the upper surface of the insulating film 25 in patterning the MTJ material layer 23 and hard mask material layer 24 into a desired shape. The etching may be done such that the upper surface of the MTJ element MTJ becomes higher than that of the insulating film 25.

According to Cell Modification 1, since the upper surface of the insulating film 25 is lower than that of the hard mask HM, the level difference between the upper surface of the insulating film 25 and that of the base metal layer 22 can be made small. For this reason, the trench 25a in the insulating film 25 can easily be filled with an insulating film.

(Cell Mofidication 2)

In Cell Modification 2, a cap layer is formed on the upper write wiring in Cell Examples 1 to 4. The structure of Cell Example 1 will be exemplified here. However, this modification can also be applied to Cell Examples 2 to 4, as a matter of course.

FIG. 28 shows Cell Modification 2 of the magnetic random access memory according to the embodiment of the present invention. In Cell Modification 2, a cap layer 41 is formed on the upper surface of the upper write wiring 26.

According to Cell Modification 2, since the cap layer 41 is formed, the upper surface of the upper write wiring 26 which is used as a mask can be suppressed from being etched.

### Cell Modification 3

In Cell Modification 3, not the upper write wiring 26 but the resist 27 is used in fabricating the MTJ element MTJ in Cell Examples 1, 2, and 4. The structure of Cell Example 1 will be exemplified here. However, this modification can also be applied to Cell Examples 2 and 4, as a matter of course.

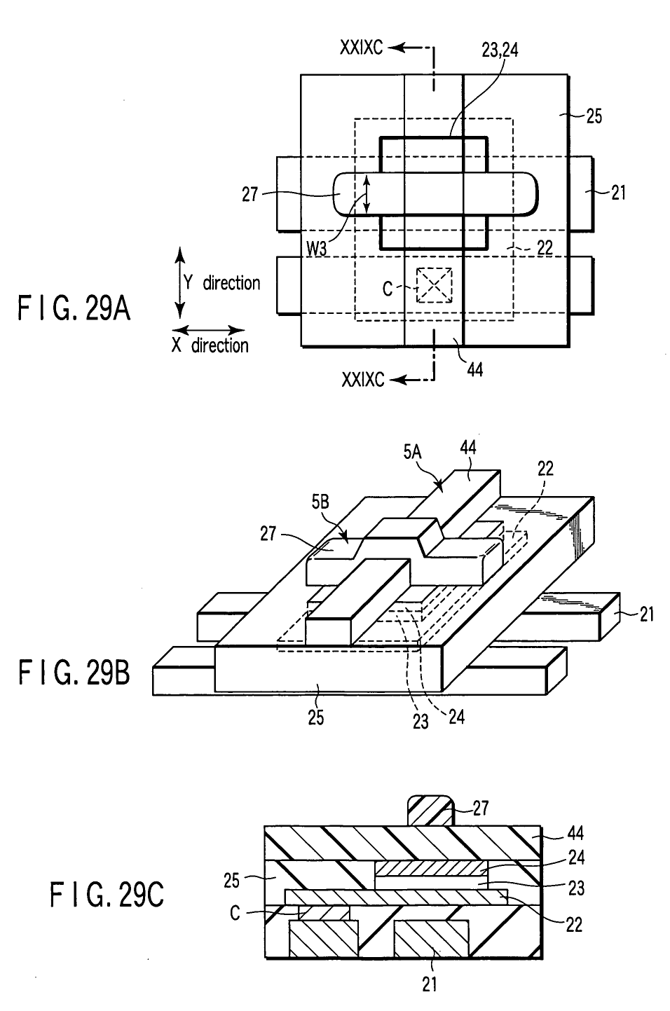

FIGS. 29A to 32C are views showing steps in manufacturing Cell Modification 3 of the magnetic random access memory according to the embodiment of the present invention. A method of manufacturing Cell Modification 3 will be described below.

First, as shown in FIGS. 29A, 29B, and 29C, a resist 44 is formed on the hard mask material layer 24 and insulating film 25 and patterned into a desired shape 5A by, e.g., lithography and RIE. The resist 27 is applied to the upper surface of the resist 44 and patterned into a desired shape 5B by, e.g., lithography and RIE. The desired shape 5B runs in the X direction across the resist 44.

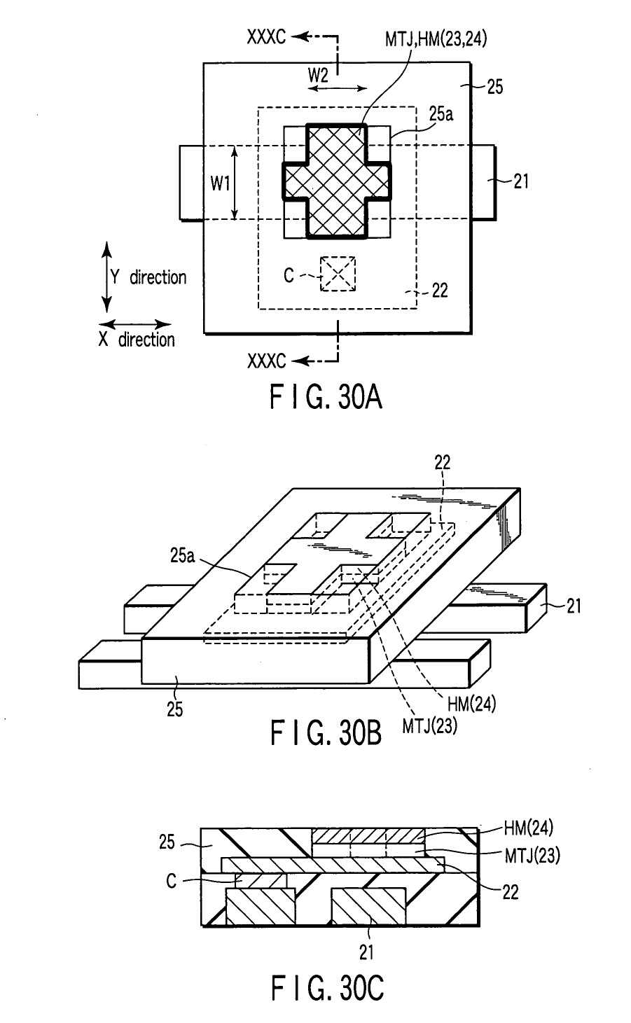

As shown in FIGS. 30A, 30B, and 30C, the hard mask material layer 24 and MTJ material layer 23 which are exposed from the resists 27 and 44 are etched by using the resists 27 and 44 as a mask. As the etching, for example, anisotropic etching (e.g., RIE), ion milling, or mixed etching of RIE and ion milling is used. As a result, the desired shapes 5A and 5B are transferred to the hard mask material layer 24 and MTJ material layer 23 so that the cross-shaped MTJ element MTJ and hard mask HM are formed. Then, the resists 27 and 44 are removed.

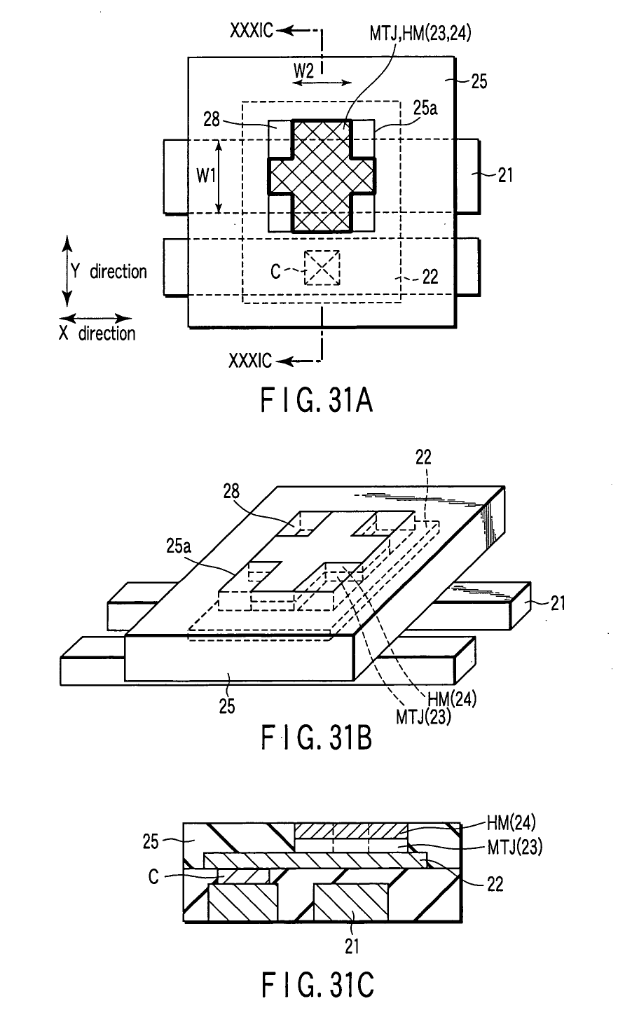

As shown in FIGS. 31A, 31B, and 31C, the insulating film 28 is deposited on the hard mask HM, insulating film 25, and base metal layer 22. The upper surface of the insulating film 28 is planarized by, e.g., CMP or etch back until the hard mask HM and insulating film 25 are exposed. Accordingly, the peripheral portion of the MTJ element MTJ and hard mask HM is filled with the insulating film 28.

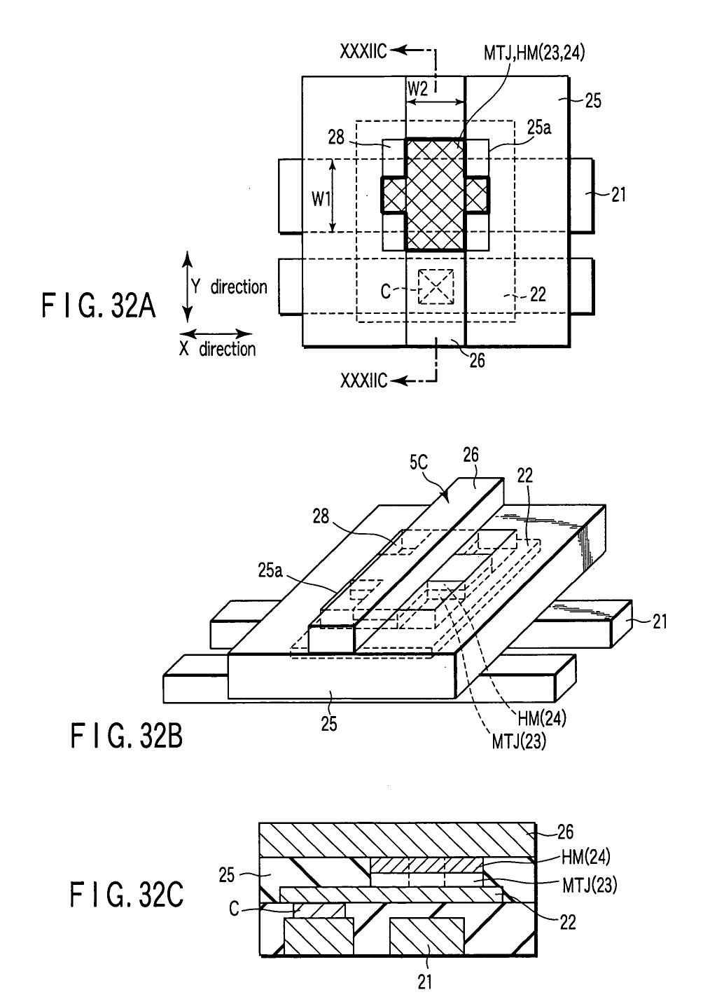

As shown in FIGS. 32A, 32B, and 32C, the upper write wiring 26 is formed and patterned into a desired shape 5C by, e.g., lithograph and RIE.

According to Cell Modification 3, not the upper write wiring 26 but the resists 27 and 44 are used in fabricating the MTJ material layer 23 and hard mask material layer 24. For this reason, the MTJ element MTJ and hard mask HM can have a shape different from the upper write wiring 26. Hence, the degree of freedom in pattern formation of the MTJ element MTJ and hard mask HM can be increased.

(Cell Modification 4)

In Cell Modification 4, a contact is used to connect the MTJ element to the upper write wiring. The structure of Cell Example 3 will be exemplified here. However, this modification can also be applied to Cell Examples 1, 2, and 4, as a matter of course.

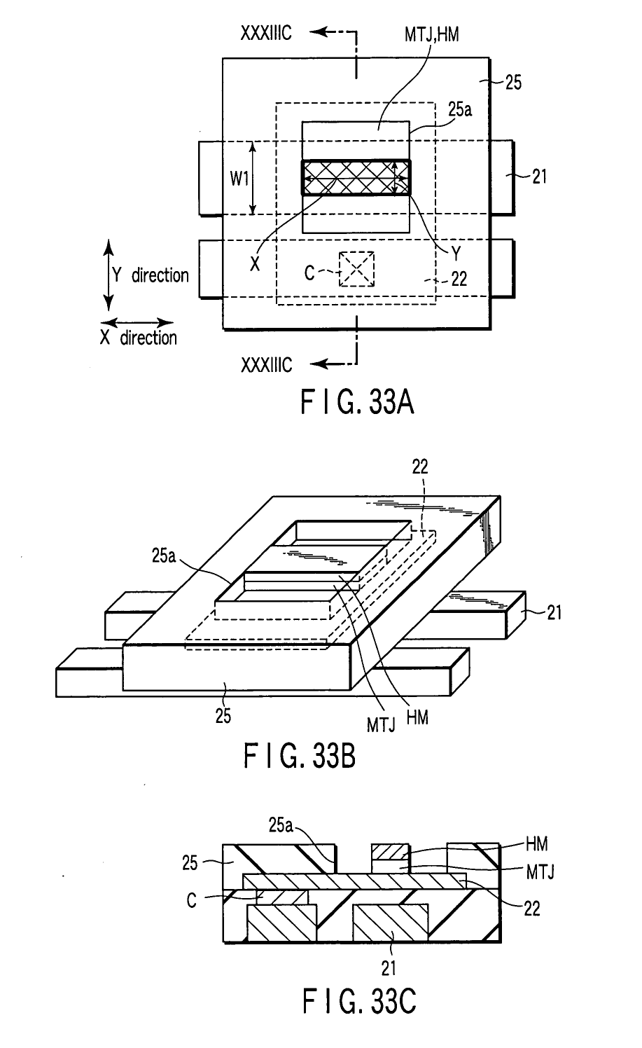

FIGS. 33A to 36C are views showing steps in manufacturing Cell Modification 4 of the magnetic random access memory according to the embodiment of the present invention. A method of manufacturing Cell Modification 4 will be described below.

First, as shown in FIGS. 33A, 33B, and 33C, the rectangular MTJ element MTJ and hard mask HM are formed.

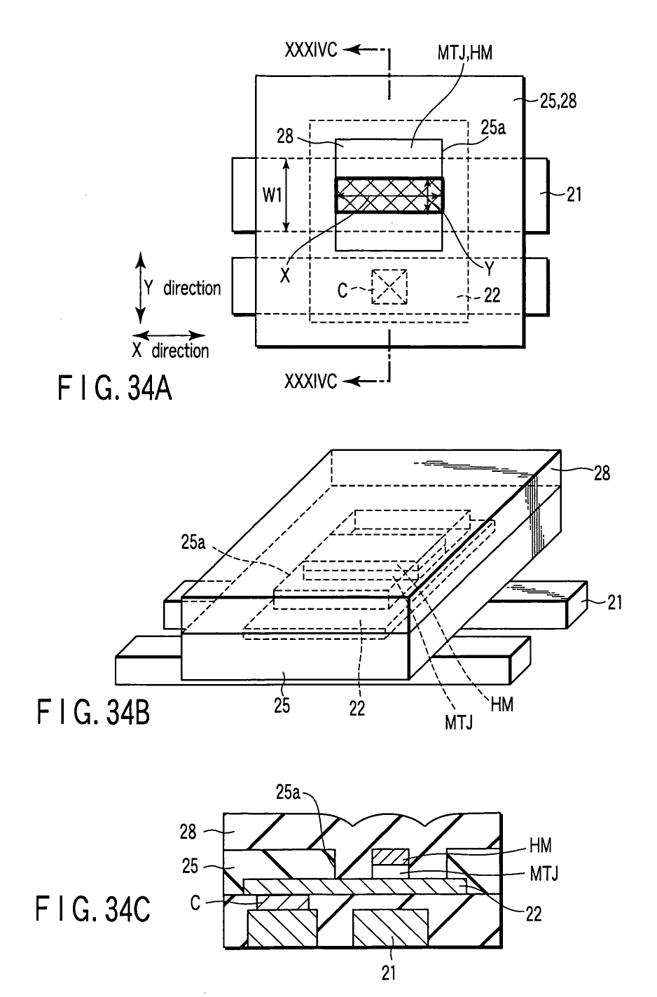

As shown in FIGS. 34A, 34B, and 34C, the insulating film 28 is deposited on the hard mask HM, insulating film 25, and base metal layer 22. The peripheral portion of the MTJ element MTJ and hard mask HM is buried with the insulating film 28. The insulating film 28 is not planarized here.

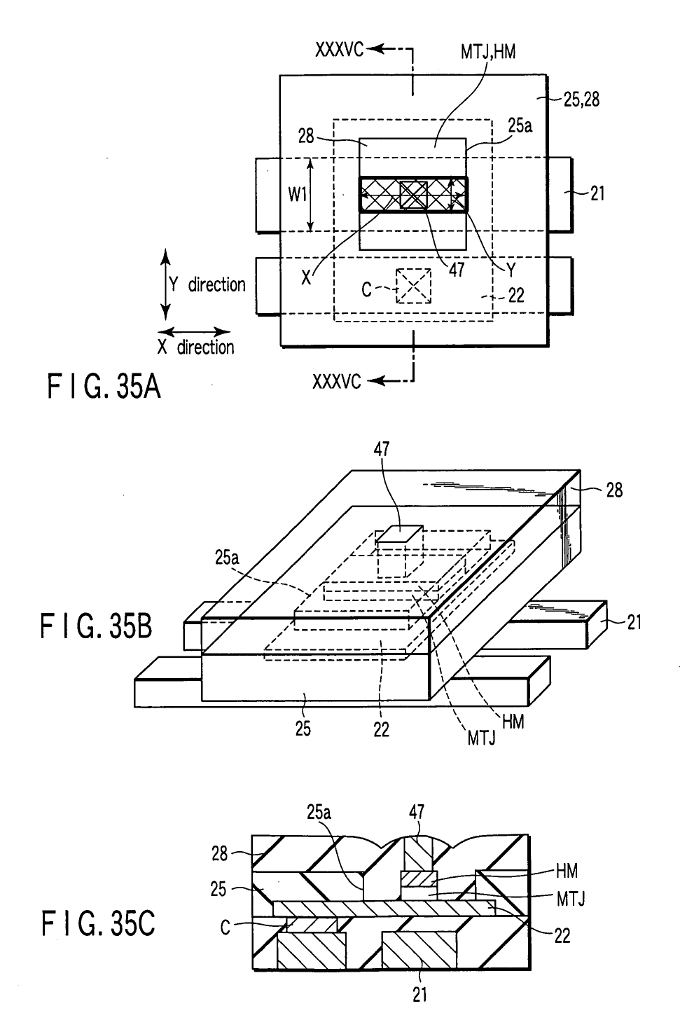

As shown in FIGS. 35A, 35B, and 35C, the insulating film 28 is selectively etched, and a metal material is buried. Accordingly, a contact 47 connected to the hard mask HM is formed.

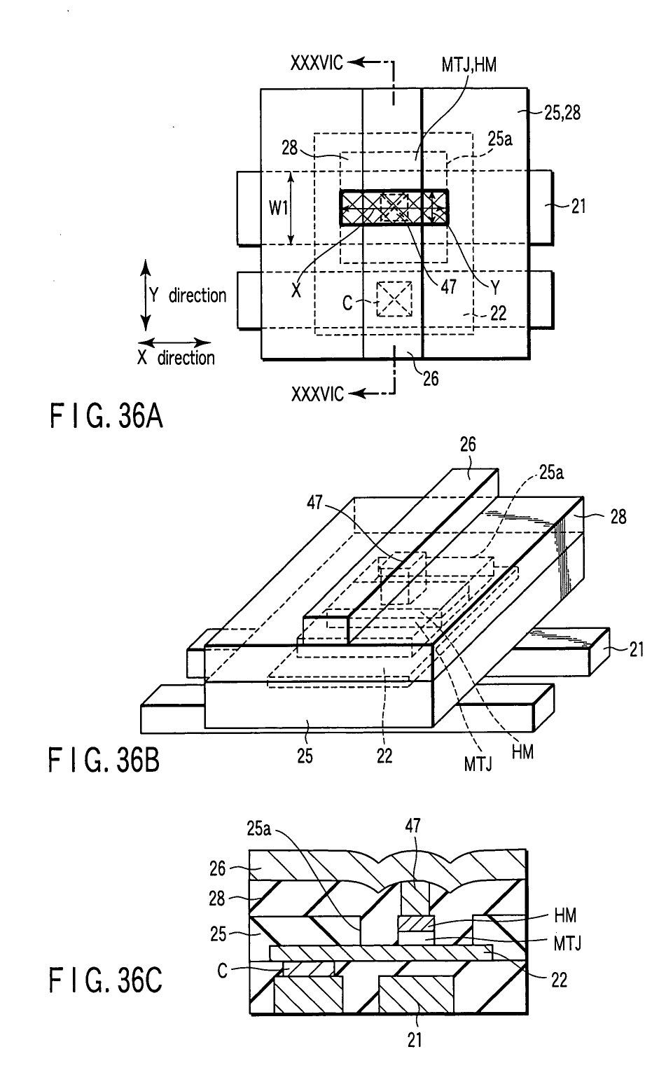

As shown in FIGS. 36A, 36B, and 36C, the upper write wiring 26 is formed on the insulating film 28 and contact 47 and patterned by, e.g., lithography and RIE.

According to Cell Modification 4, the planarization step after deposition of the insulating film 28 can be omitted.

[2-2] Write/Read Method

(Select Transistor Memory Cell)

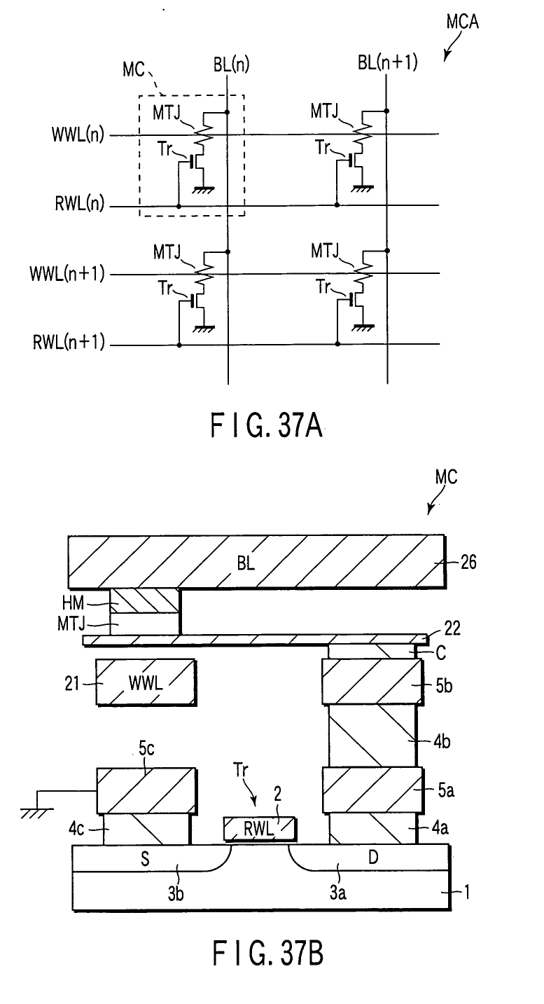

FIGS. 37A and 37B show a select transistor cell of the magnetic random access memory according to the embodiment of the present invention. The select transistor cell structure will be described below.

As shown in FIGS. 37A and 37B, one select transistor cell MC includes one MTJ element MTJ, a transistor (e.g., a MOS transistor) Tr, bit line BL, and word lines WWL and RWL.

More specifically, one terminal of the MTJ element MTJ is connected to an end (drain diffusion layer) 3a of the current path of the transistor Tr through the base metal layer 22, contacts C, 4a, 4b, and 4c, and interconnections 5a, 5b, and 5c. The other terminal of the MTJ element MTJ is connected to the upper write wiring 26 through the hard mask HM. The lower write wiring 21 electrically disconnected from the MTJ element MTJ is arranged under it. The other end (source diffusion layer) 3b of the current path of the transistor Tr is connected to, e.g., ground through the interconnection 5c. The lower write wiring 21 functions as, e.g., the write word line WWL. The upper write wiring 26 functions as, e.g., the bit line BL. The gate electrode of the transistor Tr functions as, e.g., the read word line RWL.

One terminal of the MTJ element MTJ in contact with the base metal layer 22 is, e.g., the fixed layer 12. The other terminal of the MTJ element MTJ in contact with the hard mask HM is, e.g., the recording layer 14. The arrangement may be reversed.

In this select transistor memory cell, data is written/read in the following way.

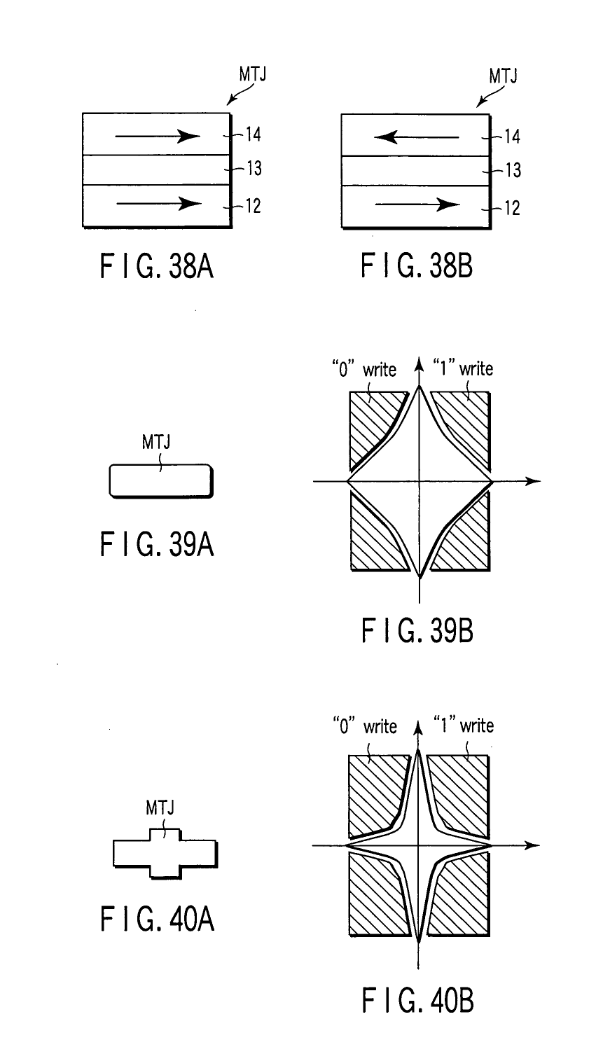

The write operation is executed in the following way. The bit line BL and write word line WWL corresponding to a selected one of the plurality of MTJ elements MTJ are selected. When write currents Iw1 and Iw2 are supplied to the selected bit line BL and write word line WWL, respectively, a synthetic field H by the write currents Iw1 and Iw2 is applied to the MTJ element MTJ. Accordingly, the magnetization of the recording layer 14 of the MTJ element MTJ is inverted so that the magnetization directions of the fixed layer 12 and recording layer 14 are parallel (same) or anti-parallel (reverse). When the parallel state is defined as a “1” state (FIG. 38A), and the anti-parallel state is defined as a “0” state (FIG. 38B), binary data can be written.

The read operation is executed in the following way. The bit line BL and read word line RWL corresponding to the selected MTJ element MTJ are selected. A read current Ir is supplied to the MTJ element MTJ. When the magnetization of the MTJ element MTJ is in the parallel state (e.g., the “1” state), the resistance is low. In the anti-parallel state (e.g., the “0” state), the resistance is high. The difference between the resistance values is read to determine the “1” or “0” state of the MTJ element MTJ.

FIG. 39B shows the asteroid curve of a rectangular MTJ element shown in FIG. 39A. FIG. 40B shows the asteroid curve of a cross-shaped MTJ element shown in FIG. 40A. As the write currents Iw1 and Iw2, current values outside the asteroid curve are used (hatched regions). As the read current Ir, a current value inside the asteroid curve is used. In these asteroid curves, the line in each quadrant more steeply curves in the asteroid curve shown in FIG. 40B than in FIG. 39B. For this reason, the cross-shaped MTJ element can more easily obtain the write current reduction effect than the rectangular MTJ element.

(Select Diode Memory Cell)

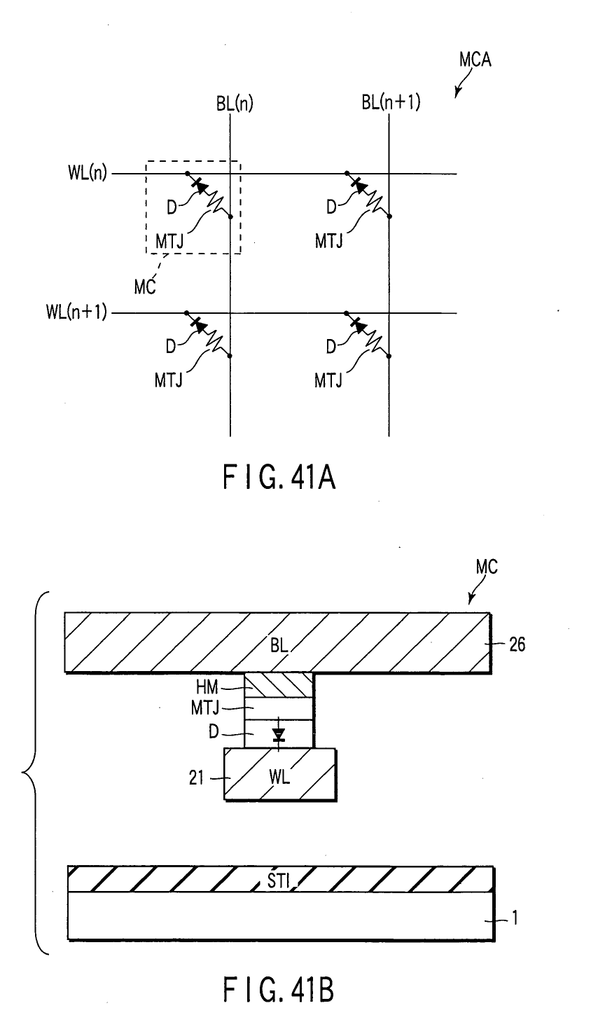

FIGS. 41A and 41B show a select diode cell of the magnetic random access memory according to the embodiment of the present invention. The select diode cell structure will be described below.

As shown in FIGS. 41A and 41B, one select diode cell MC includes one MTJ element MTJ, a diode (e.g., a p-n junction diode) D, bit line BL, and word line WL.

More specifically, one terminal (anode) of the diode D is connected to the MTJ element MTJ. The other terminal (cathode) of the diode D is connected to the word line WL. The MTJ element MTJ is connected to the bit line BL through the hard mask HM.

The diode D is formed from, e.g., a p-type semiconductor layer and an n-type semiconductor layer. In the example shown in FIGS. 41A and 41B, the p-type semiconductor layer is arranged on the side of the MTJ element MTJ. The n-type semiconductor layer is arranged on the side of the word line WL. With this structure, a current flows from the bit line BL to the word line WL.

The position and direction of the diode D can variously be changed. For example, the diode D may be arranged in a direction in which a current flows from the word line WL to the bit line BL. The diode D may be arranged between the bit line BL and the MTJ element MTJ.

In the select diode memory cell, the data write operation is the same as that of the select transistor memory cell. The write currents Iw1 and Iw2 are supplied to the bit line BL and word line WL to set the magnetization of the MTJ element MTJ in the parallel or anti-parallel state. The data read operation is also almost the same as that of the select transistor memory cell. In the select diode memory cell, however, the biases of the bit line BL and word line WL are controlled to set unselected MTJ elements in a reverse-biased state by using the rectifying effect of the diode such that the current flows to only the selected MTJ element MTJ.

(Cross-Point Memory Cell)

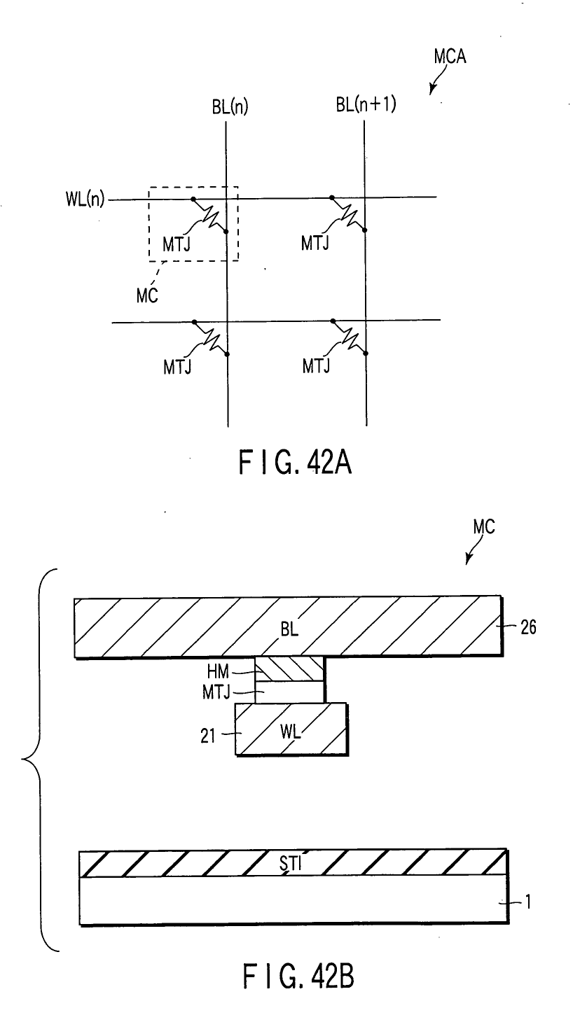

FIGS. 42A and 42B show a cross-point cell of the magnetic random access memory according to the embodiment of the present invention. The cross-point cell structure will be described below.

As shown in FIGS. 42A and 42B, one cross-point cell MC includes one MTJ element MTJ, bit line BL, and word line WL.

More specifically, the MTJ element MTJ is arranged near the intersection between the bit line BL and the word line WL. One terminal of the MTJ element MTJ is connected to the word line WL. The other terminal of the MTJ element MTJ is connected to the bit line BL through the hard mask HM.

One terminal of the MTJ element MTJ in contact with the word line WL is, e.g., the fixed layer 12. The other terminal of the MTJ element MTJ in contact with the hard mask HM is, e.g., the recording layer 14. The arrangement may be reversed.

In the cross-point memory cell, the data write operation is the same as that of the select transistor memory cell. The write currents Iw1 and Iw2 are supplied to the bit line BL and word line WL to set the magnetization of the MTJ element MTJ in the parallel or anti-parallel state. In the data read operation, currents are supplied to the bit line BL and word line WL connected to the selected MTJ element MTJ to read out the data of the MTJ element MTJ.

(Toggle Memory Cell)

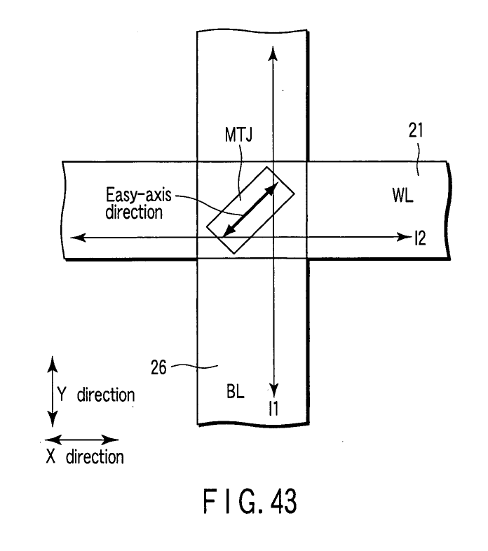

FIG. 43 shows a toggle cell of the magnetic random access memory according to the embodiment of the present invention. The toggle cell structure will be described below.

As shown in FIG. 43, in the toggle cell, the MTJ element MTJ is arranged such that its axis of easy magnetization is tilted with respect to the running direction (Y direction) of the bit line BL or the running direction (X direction) of the word line WL. The tilt of the MTJ element MTJ is, e.g., 30° to 60°, and preferably, 45°.

In the toggle cell, data is written/read in the following way.

The write operation is executed in the following way. In the toggle write, before arbitrary data is written in the selected cell, the data of the selected cell is read out. If it is determined by reading out the data of the selected cell that the arbitrary data has already been written, no write is executed. If data different from the arbitrary data is written, the write is executed to rewrite the data.

After the above-described check cycle, if data must be written in the selected cell, the two write wirings (bit line BL and word line WL) are sequentially turned on. The write wiring turned on first is turned off. Then, the write wiring turned on next is turned off. For example, the procedures comprise four cycles: the word line WL is turned on to supply the write current Iw2→the bit line BL is turned on to supply the write current Iw1→the word line WL is turned off to stop supplying the write current Iw2 the bit line BL is turned off to stop supplying the write current Iw1.

In the data read operation, currents are supplied to the bit line BL and word line WL connected to the selected MTJ element MTJ to read out the data of the MTJ element MTJ.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic random access memory comprising:
a magnetoresistive element which has a planar shape having a plurality of corners and in which at least one corner has a radius of curvature of not more than 20 nm.

2. The memory according to claim 1, which further comprises
a lower write wiring which is arranged under the magnetoresistive element and runs in a first direction, and
an upper write wiring which is arranged above the magnetoresistive element and runs in a second direction different from the first direction, and
in which at least a portion of side surfaces of the magnetoresistive element coincide with side surfaces of the upper write wiring.

3. The memory according to claim 2, wherein the planar shape of the magnetoresistive element is a cross shape, and the cross shape comprises
a main body portion which runs in the second direction and has side surfaces which coincides with the side surfaces of the upper write wiring, and
first and second projecting portions which project in the first direction from two side surfaces of the main body portion.

4. The memory according to claim 3, further comprising a hard mask which is arranged on the magnetoresistive element and has the same planar shape as the planar shape of the magnetoresistive element.

5. The memory according to claim 4, further comprising an insulating film which is formed around the magnetoresistive element and the hard mask, is in contact with end faces of the main body portion and the first and second projecting portions, and has an upper surface flush with an upper surface of the hard mask.

6. The memory according to claim 3, wherein a length of the main body portion in the second direction is larger than a width of the lower write wiring in the second direction.

7. The memory according to claim 3, wherein a length of the first and second projecting portion in the second direction are shorter than a width of the lower write wiring in the second direction.

8. The memory according to claim 3, further comprising a hard mask which is arranged on the magnetoresistive element, has a rectangular shape running in the first direction, and has side surfaces which coincide with side surfaces of the first and second projecting portions.

9. The memory according to claim 8, wherein the upper write wiring has a convex portion above the hard mask.

10. The memory according to claim 2, wherein
the planar shape of the magnetoresistive element is a rectangular shape, and
side surfaces of the rectangular shape coincide with the side surfaces of the upper write wiring.

11. The memory according to claim 1, wherein the magnetoresistive element comprises
a main body portion which runs in a direction of axis of easy magnetization, and
a projecting portion which projects in a direction of axis of hard magnetization from a side surface of the main body portion.

12. The memory according to claim 1, wherein the magnetoresistive element includes
a fixed layer which has fixed magnetization,
a recording layer which has variable magnetization, and
an intermediate layer which is arranged between the fixed layer and the recording layer, and
at least a portion of side surfaces of the fixed layer, the recording layer, and the intermediate layer coincide with each other.

13. The memory according to claim 1, wherein the magnetoresistive element has one of a single tunnel junction structure and a double tunnel junction structure.

14. The memory according to claim 1, wherein the magnetoresistive element includes
a fixed layer which has fixed magnetization,
a recording layer which has variable magnetization, and
an intermediate layer which is arranged between the fixed layer and the recording layer, and
at least one of the fixed layer and the recording layer is formed from a layered film including a first ferromagnetic layer, a nonmagnetic layer, and a second ferromagnetic layer, and magnetic coupling occurs to set magnetization directions of the first ferromagnetic layer and the second ferromagnetic layer in one of a parallel state and an anti-parallel state.

15. A method of manufacturing a magnetic random access memory, comprising:
forming a lower write wiring which runs in a first direction;
sequentially forming a first material layer serving as a magnetoresistive element and a second material layer serving as a hard mask above the lower write wiring;
patterning the first material layer and the second material layer into a first shape;
forming a resist which runs in the first direction across the first shape;
patterning the second material layer by using the resist as a mask to form the hard mask having a second shape;
removing the resist;
forming an insulating film around the first material layer, the insulating film exposing the hard mask and the first material layer;
forming an upper write wiring which runs in a second direction different from the first direction across the first shape; and
patterning the first material layer by using the upper write wiring and the hard mask as a mask to form the magnetoresistive element having a third shape, the magnetoresistive element having corners whose radius of curvature is not more than 20 nm.

16. The method according to claim 15, wherein the second shape is a rectangular shape, and the third shape is a cross shape.

17. A method of manufacturing a magnetic random access memory, comprising:
forming a lower write wiring which runs in a first direction;
forming a material layer serving as a magnetoresistive element above the lower write wiring;
patterning the material layer into a first shape;
forming a first insulating film around the material layer, the first insulating film exposing the material layer;
forming a resist which runs in the first direction across the first shape;
patterning the material layer by using the resist as a mask to form the magnetoresistive element having a second shape, the magnetoresistive element having corners whose radius of curvature is not more than 20 nm;
removing the resist; and
forming an upper write wiring which runs in a second direction different from the first direction across the first shape.

18. The method according to claim 17, further comprising
after the resist is removed before the upper write wiring is formed,
forming a second insulating film on the first insulating film and the magnetoresistive element, and
forming, in the second insulating film, a contact to be connected to the magnetoresistive element.

19. A method of manufacturing a magnetic random access memory, comprising:
forming a lower write wiring which runs in a first direction;
forming a material layer serving as a magnetoresistive element above the lower write wiring;
patterning the material layer into a first shape;
forming an insulating film around the material layer, the insulating film exposing the material layer;
forming an upper write wiring which runs in a second direction different from the first direction across the first shape; and
patterning the material layer by using the upper write wiring as a mask to form the magnetoresistive element having a second shape, the magnetoresistive element having corners whose radius of curvature is not more than 20 nm.

20. The method according to claim 19, which further comprises after the upper write wiring is formed, forming a resist which runs in the first direction across the upper write wiring and the first shape, and
in which the material layer is patterned by using the upper write wiring and the resist as a mask.
